(19) United States
(12) Patent Application Publication
(10) Pub. No.: US 2025/0294818 A1
(43) Pub. Date: Sep. 18, 2025

(54) TRANSISTOR DESIGNS FOR FLOATING BODY MEMORY

(71) Applicant: Intel Corporation, Santa Clara, CA (US)

(72) Inventors: Abhishek A. Sharma, Portland, OR (US); Anand S. Murthy, Portland, OR (US); Tahir Ghani, Portland, OR (US); Wilfred Gomes, Portland, OR (US)

(73) Assignee: Intel Corporation, Santa Clara, CA (US)

(21) Appl. No.: 18/602,138

(22) Filed: Mar. 12, 2024

(51) Int. Cl. H01L 29/78; H01L 27/02; H01L 29/06; H10B 12/00

(52) U.S. Cl. CPC H10D 30/711; H10B 12/20; H10D 62/10; H10D 89/00

(57) ABSTRACT

Transistor designs for floating body memory, and associated devices and systems, are disclosed. In one aspect, a transistor of a floating body memory cell includes a layer of a first semiconductor material between a first S/D contact and a first S/D region of the transistor, and a layer of a second semiconductor material between a second S/D contact and a second S/D region of the transistor, where the first and second semiconductor materials differ in at least one of a thickness, a bandgap, or a doping concentration.

### BACKGROUND

Floating body memory is a type of non-volatile memory that relies on the charge storage in a floating body layer. While it has some potential advantages over other memory types, such as low power consumption and compatibility with standard semiconductor manufacturing processes, there are several challenges associated with its implementation and, therefore, further improvements are desirable.

### BRIEF DESCRIPTION OF THE DRAWINGS

Embodiments will be readily understood by the following detailed description in conjunction with the accompanying drawings.

FIGS. 1A-1F are cross-sectional side views of example transistors that may be used in floating body memory, in accordance with various embodiments.

FIG. 2 is an electric circuit diagram of a first example array of floating body memory cells, according to some embodiments of the present disclosure.

FIG. 3 is an electric circuit diagram of a second example array of floating body memory cells, according to some embodiments of the present disclosure.

FIG. 4 is a cross-sectional side view of an example integrated circuit (IC) structure implementing floating body memory according to the electric circuit diagram of FIG. 2, according to some embodiments of the present disclosure.

FIGS. 5A-5B are cross-sectional side views of example IC structures implementing floating body memory according to the electric circuit diagram of FIG. 3, according to some embodiments of the present disclosure.

FIGS. 6A-6D are cross-sectional side views of example asymmetric transistors that may be used in floating body memory, according to some embodiments of the present disclosure.

FIG. 7 provides top views of a wafer and dies that may include one or more IC structures implementing floating body memory in accordance with any of the embodiments disclosed herein.

FIG. 8 is a cross-sectional side view of an IC package that may include one or more IC structures implementing floating body memory in accordance with any of the embodiments disclosed herein.

FIG. 9 is a cross-sectional side view of an IC device assembly that may include one or more IC structures implementing floating body memory in accordance with any of the embodiments disclosed herein.

FIG. 10 is a block diagram of an example computing device that may include one or more IC structures implementing floating body memory in accordance with any of the embodiments disclosed herein.

FIG. 11 is a block diagram of an example processing device that may include one or more IC structures implementing floating body memory in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating transistor designs for floating body memory as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

Some memory devices may be considered “standalone” devices in that they are included in a chip that does not also include compute logic (where, as used herein, the term “compute logic devices” or simply “compute logic” or “logic devices,” refers to IC components, e.g., transistors, for performing computing/processing operations). Other memory devices may be included in a chip along with compute logic and may be referred to as “embedded” memory devices. Using embedded memory to support compute logic may improve performance by bringing the memory and the compute logic closer together and eliminating interfaces that increase latency. Various embodiments of the present disclosure relate to embedded memory arrays, as well as corresponding methods and devices.

Access transistors have been used in the past to realize memory where each memory cell includes one capacitor for storing a memory state (e.g., logical “1” or “0”) of the cell and an access transistor controlling access to the cell (e.g., access to write information to the cell or access to read information from the cell). Such a memory cell may be referred to as a “1T-1C memory cell,” highlighting the fact that it uses one access transistor (i.e., “1T” in the term “1T-1C memory cell”) and one capacitor (i.e., “1C” in the term “1T-1C memory cell”). One capacitor electrode of the capacitor of a 1T-1C memory cell may be coupled to either a source or a drain (S/D) terminal/region of the access transistor (e.g., to the source terminal/region of the access transistor), while the other S/D terminal/region of the access transistor (e.g., to the drain terminal/region) may be coupled to a bitline, a gate terminal of the access transistor may be coupled to a wordline, and the other capacitor electrode of the capacitor may be coupled to a plateline. Since such a memory cell can be fabricated with as little as a single access transistor, it can provide higher density and lower standby power versus some other types of memory in the same process technology.

Floating body memory, e.g., floating body dynamic random-access memory (FBDRAM) is a popular choice for various types of computer systems because it is even simpler than 1T-1C memory in that it only uses a single transistor as a memory cell. Thus, such memory cells may be referred to as “1T” memory cells. In floating body memory, a memory cell (also referred to as a “floating body memory cell”) may use the floating body of a single transistor to store data, which, compared to 1T-1C memory, eliminates the need to use a capacitor to store charge representing a memory state. In a conventional floating body memory cell, a first S/D region is coupled to a first control line (e.g., a bitline), a second S/D region is coupled to a second control line (e.g., a selectline), and a gate of the transistor is coupled to a third control line (e.g., a wordline). Voltages may then be applied to the first, second, and third control lines to read and write data of such a floating body memory cell.

In some deployment scenarios, floating body memory cells may be more advantageous than traditional memory cells, given their simple structure and high scalability. However, as briefly mentioned above, there are also challenges associated with this type of memory. One significant challenge is achieving long-term data retention. The stored charge in the floating body can slowly leak over time, leading to potential data loss. Ensuring stable and reliable data retention is crucial for non-volatile memory applications. Another challenge is that the performance of floating body memory can be sensitive to temperature variations. Temperature fluctuations can affect the charge retention properties and overall reliability of the memory, requiring additional measures for temperature compensation. Yet another challenge resides in achieving sufficiently fast read and write speeds, which are crucial for memory devices in certain applications. Furthermore, as technology advances, there is a continual push for smaller device sizes and increased memory density. Scaling floating body memory to smaller dimensions may introduce additional challenges related to charge confinement, leakage, and overall device reliability.

Transistor designs for floating body memory, and associated devices and systems, are disclosed. In one aspect, a transistor of a floating body memory cell includes a layer of a first semiconductor material between a first S/D contact and a first S/D region of the transistor, and a layer of a second semiconductor material between a second S/D contact and a second S/D region of the transistor, where the first and second semiconductor materials differ in at least one of a thickness, a bandgap, or a doping concentration. Such a transistor may be referred to as an “asymmetric transistor.” In some embodiments, a thickness of a semiconductor material between a S/D contact and a S/D region on the write side of a transistor may be smaller than a thickness of a semiconductor material between a S/D contact and a S/D region on the read side, e.g., at least about 10% smaller or at least about 15% smaller. In some embodiments, a dopant concentration of a semiconductor material between a S/D contact and a S/D region on the write side of a transistor may be higher than a dopant concentration of a semiconductor material between a S/D contact and a S/D region on the read side, e.g., at least about 2 times higher or at least about 5 times higher. In some embodiments, a bandgap of a semiconductor material between a S/D contact and a S/D region on the write side of a transistor may be smaller (which may also be described as “narrower”) than a bandgap of a semiconductor material between a S/D contact and a S/D region on the read side, e.g., at least about 0.08 electron-Volt (eV) smaller or at least about 0.1 eV smaller. Inventors of the present disclosure recognized that, when the first S/D contact is used to write data to such a memory cell and the second S/D contact is used to read data from the memory cell, then having differences in ranges described herein in one or more of a thickness, a bandgap, or a doping concentration of the semiconductor materials introduced on the write side and the read side of the transistor may improve performance in terms of charge confinement, leakage, and overall device reliability.

Further improvements to conventional implementations of floating body memory may be achieved by implementing transistors of floating body memory cell as thin-film transistors (TFTs). A TFT is a special kind of a field-effect transistor made by depositing a thin film of an active semiconductor material over a supporting layer that may be a non-conducting layer. At least a portion of the active semiconductor material forms a channel of the TFT. This is different from conventional, non-TFT, front end of line (FEOL) transistors where the active semiconductor channel material is an epitaxially grown semiconductor material and is typically a part of a semiconductor substrate, e.g., a part of a silicon wafer. Using TFTs as memory cells of floating body memory provides several advantages and enables unique architectures that were not possible with conventional, FEOL transistors. One advantage is that the bandgap of thin-film semiconductor materials can be modified much easier compared to epitaxially grown semiconductor materials such as silicon, germanium, or silicon germanium, typically used in FEOL transistors. Another advantage is that TFTs may be moved to the back end of line (BEOL) layers of an advanced complementary metal-oxide-semiconductor (CMOS) process, which means that memory cells may be provided in different layers above a substrate, thus enabling a stacked architecture of memory arrays. In this context, the term “above” refers to being further away from the substrate or the FEOL of an IC device, while the term “below” refers to being closer towards the substrate or the FEOL of the IC device. Still further, when transistors are implemented as TFTs, memory cells may be provided on both sides of a substrate, and at least portions of some memory cells may be provided in different layers on each side of the substrate.

Any of the asymmetric transistors described herein may be implemented as a TFT in some embodiments. However, in another aspect, embodiments of the present disclosure may improve on at least some of the challenges and issues described above by providing a TFT that may, but does not have to be, an asymmetric transistor as described herein, but where a difference between a work function of the first/second S/D contact and a conduction band of the channel portion is less than about 0.5 eV, and where a bandgap of the channel portion is between about 0.7 eV and about 2 eV. Inventors of the present disclosure recognized that such requirements on the selection of materials used in a transistor of a floating body memory cell may also improve performance in terms of charge confinement, leakage, and overall device reliability.

Floating body memory as described herein may be used to address the scaling challenges of conventional memory technologies and enable high density embedded memory compatible with advanced CMOS processes. Other technical effects will be evident from various embodiments described here.

In the following detailed description, various aspects of the illustrative implementations may be described using terms commonly employed by those skilled in the art to convey the substance of their work to others skilled in the art. For example, as used herein, the term “high-k dielectric” refers to a material having a higher dielectric constant (k) than silicon oxide, while the term “low-k dielectric” refers to a material having a lower k than silicon oxide. If used, the terms “oxide,” “carbide,” “nitride,” etc. refer to compounds containing, respectively, oxygen, carbon, nitrogen, etc. As used herein, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. As used herein, A connected to B may include A being in physical contact (e.g., in direct physical contact) with B; if one or more interfacial layers may form when A and B are brought into direct physical contact, then such interfacial layers may be considered to be a part of A and/or a part of B. The term “circuit” means one or more passive and/or active components that are arranged to cooperate with one another to provide a desired function. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

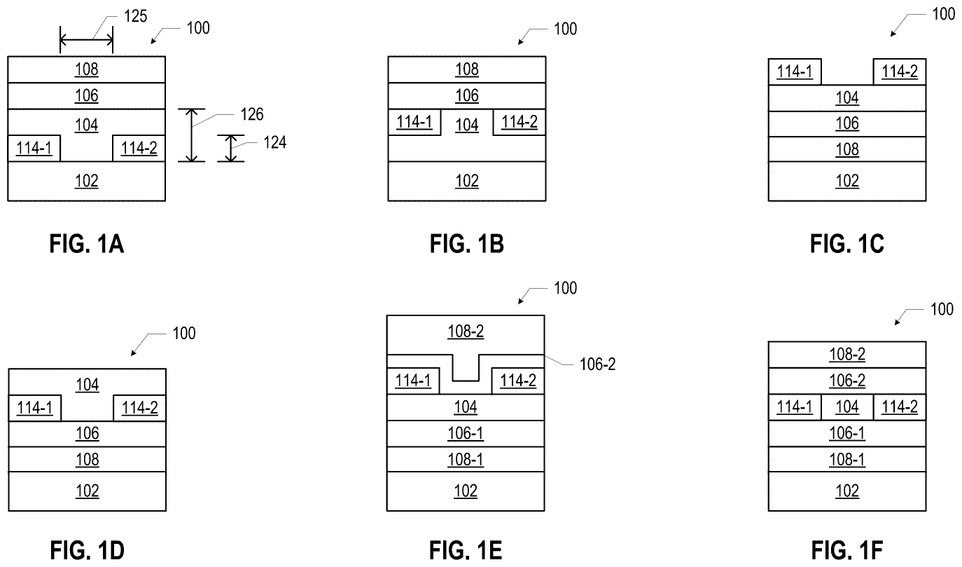

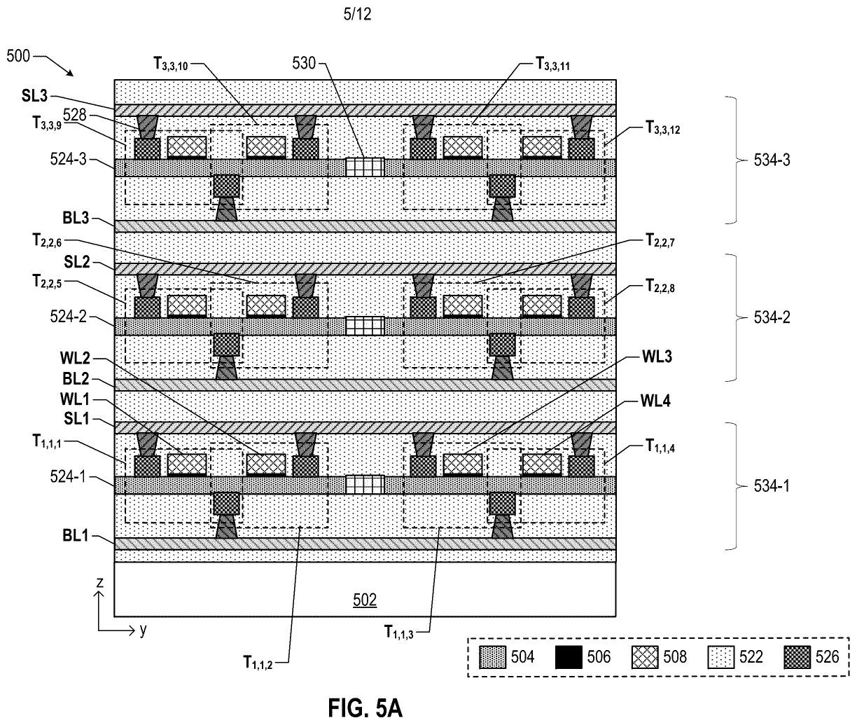

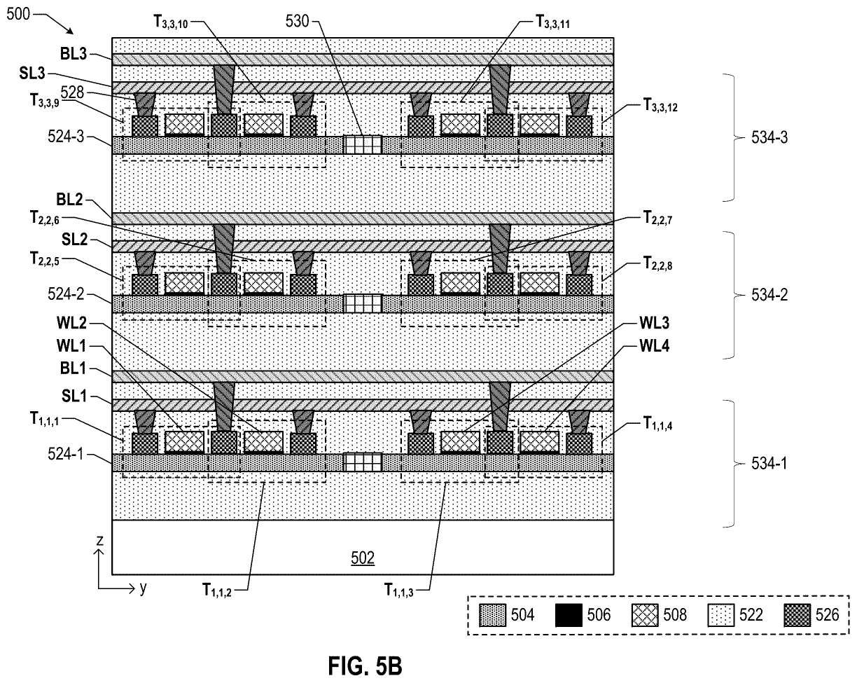

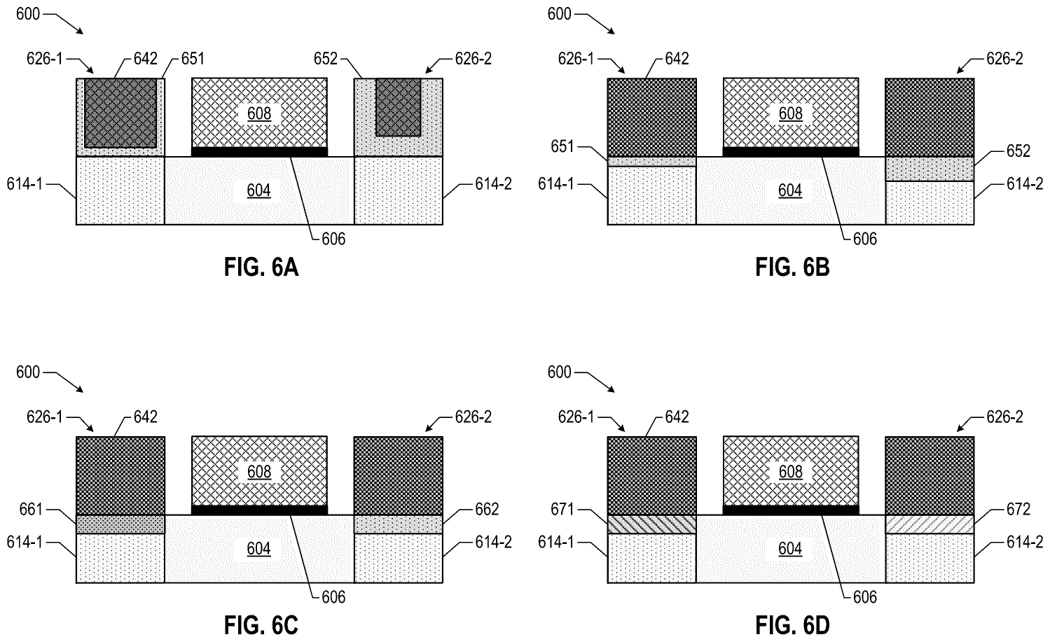

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, analogous elements designated in the present drawings with different reference numerals after a dash, e.g., first and second S/D regions 114-1, 114-2 may be referred to together without the reference numerals after the dash, e.g., as “S/D regions 114.” In order to not clutter the drawings, if multiple instances of certain elements are illustrated, only some of the elements may be labeled with a reference sign. For convenience, the phrase “FIG. 1” may be used to refer to the collection of drawings of FIGS. 1A-1F, the phrase “FIG. 5” may be used to refer to the collection of drawings of FIGS. 5A-5B, and the phrase “FIG. 6” may be used to refer to the collection of drawings of FIGS. 6A-6D.

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of transistor designs for floating body memory as described herein.

Various transistor designs for floating body memory as described herein may be implemented in, or associated with, one or more components associated with an IC (e.g., an IC structure or an IC device) or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

FIGS. 1A-1F are cross-sectional side views of example transistors that may be used in floating body memory, in accordance with various embodiments. For example, any of the transistors shown in FIGS. 1A-1F may be implemented as asymmetric transistors as described with reference to FIGS. 6A-6D. As shown in FIGS. 1A-1F, a transistor 100 may include a channel material 104, a gate insulator 106, a gate electrode material 108, a first S/D region 114-1 (e.g., a source region), and a second S/D region 114-2 (e.g., a drain region).

The channel material 104 may be composed of semiconductor material systems including, for example, N-type or P-type materials systems. In some embodiments, the channel material 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 104 may include a combination of semiconductor materials. In some embodiments, the channel material 104 may include a monocrystalline semiconductor, such as silicon (Si) or germanium (Ge). In some embodiments, the channel material 104 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (e.g., for the embodiments where a transistor 100 of any of FIGS. 1A-1F is an N-type metal-oxide-semiconductor (NMOS) transistor), the channel material 104 may include a III-V material having a relatively high electron mobility, such as, but not limited to InGaAs, InP, InSb, and InAs. For some such embodiments, the channel material 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (e.g., for the embodiments where a transistor 100 of any of FIGS. 1A-1F is a P-type metal-oxide-semiconductor (PMOS) transistor), the channel material 104 may advantageously be a group IV material having a high hole mobility, such as, but not limited to Ge or a Ge-rich SiGe alloy. For some example embodiments, the channel material 104 may have a Ge content between 0.6 and 0.9, and advantageously may be at least 0.7.

In some embodiments, the channel material 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if a transistor is a TFT, the channel material 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, a thickness of the channel material 104 may be between about 5 and 75 nanometers, including all values and ranges therein, e.g., between about 5 and 30 nanometers.

The gate electrode material 108 may include at least one P-type work function metal or N-type work function metal, depending on whether the gate electrode material 108 is to be included in a P-type transistor or an N-type transistor. For a P-type transistor, metals that may be used for the gate electrode material 108 may include, but are not limited to, ruthenium, palladium, platinum, cobalt, nickel, and conductive metal oxides (e.g., ruthenium oxide). For an N-type transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of two or more metal layers, where one or more metal layers are work function metal layers and at least one metal layer is a fill metal layer. Further metal layers may be included for other purposes, such as to act as a barrier layer.

A gate insulator 106 may be disposed between the gate electrode material 108 and the channel material 104, and, together, the gate insulator 106 and the gate electrode material 108 may form a gate stack of the transistor 100. In some embodiments, the gate insulator 106 may include one or more high-k dielectrics, e.g., insulator materials including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate insulator 106 during fabrication of the transistor 100 to improve the quality of the gate insulator 106. The gate insulator 106 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack of the transistor 100 may be surrounded by a gate spacer, not shown in the present drawings. Such a gate spacer would be configured to provide separation between the gate stack and source/drain contacts of the transistor 100 and could be made of a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass. A gate spacer may include pores or air gaps to further reduce its dielectric constant.

In some embodiments, e.g., when the transistor 100 is a storage transistor of a hysteretic memory cell (i.e., a type of memory that functions based on the phenomenon of hysteresis), the gate insulator 106 may be replaced with, or complemented by, a hysteretic material or a hysteretic arrangement, which, together, may be referred to as a “hysteretic element.” Transistors 100 in which the gate insulator 106 includes a hysteretic element may be described as “hysteretic transistors” and may be used to implement hysteretic memory. Hysteretic memory refers to a memory technology employing hysteretic materials or arrangements, where a material or an arrangement may be described as hysteretic if it exhibits the dependence of its state on the history of the material (e.g., on a previous state of the material). Ferroelectric (FE) and antiferroelectric (AFE) materials are one example of hysteretic materials. Layers of different materials arranged in a stack to exhibit charge-trapping phenomena is one example of a hysteretic arrangement.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, such materials may be used to implement memory cells. Because the current state of the electric dipoles in FE and AFE materials depends on the previous state, such materials are hysteretic materials. Memory technology where logic states are stored in terms of the orientation of electric dipoles in (i.e., in terms of polarization of) FE or AFE materials is referred to as “FE memory,” where the term “ferroelectric” is said to be adopted to convey the similarity of FE memories to ferromagnetic memories, despite the fact that there is typically no iron (Fe) present in FE or AFE materials.

A stack of alternating layers of materials that is configured to exhibit charge-trapping is an example of a hysteretic arrangement. Such a stack may include as little as two layers of materials, one of which is a charge-trapping layer (i.e., a layer of a material configured to trap charges when a voltage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, such arrangements may be used to implement memory cells. Because the presence and/or the amount of trapped charges in a charge-trapping arrangement depends on the previous state, such arrangements are hysteretic arrangements. Memory technology where logic states are stored in terms of the amount of charge trapped in a hysteretic arrangement may be referred to as “charge-trapping memory.”

Hysteretic memories have the potential for adequate non-volatility, short programming time, low power consumption, high endurance, and high-speed writing. In addition, hysteretic memories may be manufactured using processes compatible with the standard CMOS technology. Therefore, over the last few years, these types of memories have emerged as promising candidates for many growing applications.

In some embodiments, the hysteretic element of the gate insulator 106 may be provided as a layer of a FE or an AFE material. Such an FE/AFE material may include one or more materials that can exhibit sufficient FE/AFE behavior even at thin dimensions, e.g., such as an insulator material at least about 5%, e.g., at least about 7% or at least about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic element and are within the scope of the present disclosure.

In other embodiments, the hysteretic element of the gate insulator 106 may be provided as a stack of alternating layers of materials that can trap charges. In some such embodiments, the stack may be a two-layer stack, where one layer is a charge-trapping layer and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material. In some embodiments, the charge-trapping layer may include a material that includes silicon and nitrogen (e.g., silicon nitride). In general, any material that has defects that can trap charge may be used in/as a charge-trapping layer. Such defects are very detrimental to operation of logic devices and, therefore, typically, deliberate steps need to be taken to avoid presence of the defects. However, for memory devices, such defects are desirable because charge-trapping may be used to represent different memory states of a memory cell.

In some embodiments of the hysteretic element being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.”

In various embodiments of the hysteretic element being provided as a stack of alternating layers of materials that can trap charges, a thickness of each layer the stack may be between about 0.5 and 10 nanometers, including all values and ranges therein, e.g., between about 0.5 and 5 nanometers. In some embodiment of a three-layer stack, a thickness of each layer of the insulator material may be about 0.5 nanometers, while a thickness of the charge-trapping layer may be between about 1 and 8 nanometers, e.g., between about 2.5 and 7.5 nanometers, e.g., about 5 nanometers. In some embodiments, a total thickness of the hysteretic element provided as a stack of alternating layers of materials that can trap charges (i.e., a hysteretic arrangement) may be between about 1 and 10 nanometers, e.g., between about 2 and 8 nanometers, e.g., about 6 nanometers.

Turning to the S/D regions 114 of the transistor 100, in some embodiments, the S/D regions may be highly doped, e.g., with dopant concentrations of at least about 1×10¹⁸ dopants per cubic centimeter (cm⁻³), e.g., of at least about 1×10²⁰ cm⁻³, or of at least about 1×10²¹ cm⁻³, in order to advantageously form Ohmic contacts with the respective S/D contacts/electrodes (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a portion of the channel material 104 that extends between the first S/D region 114-1 and the second S/D region 114-2), and, therefore, may be referred to as “highly doped” (HD) regions. Even with doped to realize threshold voltage tuning as described herein, the channel portions of transistors typically include semiconductor materials with doping concentrations significantly smaller than those of the S/D regions 114.

The S/D regions 114 of the transistor 100 may generally be formed using either an implantation/diffusion process or an etching/deposition process. In the former process, dopants such as boron, aluminum, antimony, phosphorous, or arsenic may be ion-implanted into the channel material 104 to form the source and drain regions. An annealing process that activates the dopants and causes them to diffuse further into the channel material 104 may follow the ion implantation process. In the latter process, portions of the channel material 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 may be between about 5 and 40 nanometers, including all values and ranges therein (e.g., between about 22 and 35 nanometers, or between about 20 and 30 nanometers).

IC structures with the transistors 100 as shown in FIG. 1, as well as IC structures/devices shown in other drawings of the present disclosure, is intended to show relative arrangements of some of the components therein, and the IC structures, or portions thereof, may include other components that are not illustrated (e.g., electrical contacts to the S/D regions 114 of the transistor 100, additional layers such as a spacer layer around the gate electrode of the transistor 100, etc.).

FIGS. 1A-1D are cross-sectional side views of example single-gate transistors 100, while FIGS. 1E-1F are cross-sectional side views of example double-gate transistors 100.

FIG. 1A depicts a transistor 100 having a single “top” gate provided by the gate electrode material 108 and the gate insulator 106). The gate insulator 106 may be disposed between the gate electrode material 108 and the channel material 104. The gate insulator 106 may border the channel material 104; in particular, the gate insulator 106 may contact the channel material 104 without any intervening material in some embodiments. In the embodiment of FIG. 1A, a portion of the channel material 104, as well as the first S/D region 114-1 and the second S/D region 114-2 are shown as disposed over a support 102.

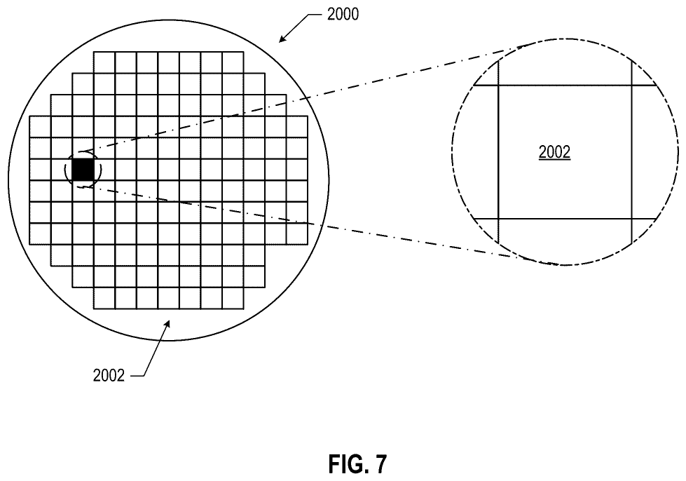

The support 102 may be any structure, e.g., a substrate, a die, a wafer, or a chip, over which the transistor 100 or larger IC structures incorporating the transistor 100, may be disposed. The support 102 may, e.g., be the wafer 2000 of FIG. 7, discussed below, and may be, or be included in, a die, e.g., the singulated die 2002 of FIG. 7, discussed below. In some embodiments, the support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups Il and IV of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die. In some embodiments, the support 102 may include an insulating layer, such as an oxide isolation layer. For example, in the embodiments of FIGS. 1A and 1B, the support 102 may include a semiconductor material and an interface layer dielectric (ILD) disposed between the semiconductor material and the first S/D region 114-1, the channel material 104, and the second S/D region 114-2, to electrically isolate the semiconductor material of the support 102 from the first S/D region 114-1, the channel material 104, and the second S/D region 114-2 (and thereby mitigate the likelihood that a conductive pathway will form between the first S/D region 114-1 and the second S/D region 114-2 through the support 102). Examples of ILDs that may be included in a support 102 in some embodiments may include silicon oxide, silicon nitride, aluminum oxide, and/or silicon oxynitride. Any suitable ones of the embodiments of the support 102 described with reference to FIG. 1A may be used for the supports 102 of others of the transistors disclosed herein.

As shown in FIG. 1A, in some embodiments, the first S/D region 114-1 and the second S/D region 114-2 may have a thickness 124, and the channel material 104 may have a thickness 126. The thickness 126 may be between about 5 and 75 nanometers, including all values and ranges therein, e.g., between about 5 and 30 nanometers. In some embodiments, the thickness 124 may be less than the thickness 126 (as illustrated in FIG. 1A, with the first S/D region 114-1 and the second S/D region 114-2 each disposed between some of the channel material 104 and the support 102), while in other embodiments, the thickness 124 may be equal to the thickness 126. In some embodiments, the channel material 104, the gate insulator 106, and/or the gate electrode material 108 may conform around the first S/D region 114-1 and/or the second S/D region 114-2. The first S/D region 114-1 and the second S/D region 114-2 may be spaced apart by a distance 125 that is the gate length of the transistor 100. In some embodiments, the gate length may be between about 5 and 40 nanometers, including all values and ranges therein (e.g., between about 22 and 35 nanometers, or between about 20 and 30 nanometers).

FIG. 1B depicts a transistor 100 having a single “top” gate provided by the gate electrode material 108 and the gate insulator 106. The transistor 100 of FIG. 1B is similar to that shown in FIG. 1A, except that, in the embodiment of FIG. 1B, the channel material 104 is shown as disposed over the support 102, while the first S/D region 114-1 and the second S/D region 114-2 are separated from the support 102 by portions of the channel material 104. As shown in FIG. 1B, at least some of the channel material 104 may be coplanar with at least some of the first S/D region 114-1 and the second S/D region 114-2.

FIG. 1C depicts a transistor 100 having a single “bottom” gate provided by the gate electrode material 108 and the gate insulator 106. The gate insulator 106 may be disposed between the gate electrode material 108 and the channel material 104. In the embodiment of FIG. 1C, the gate insulator 106 may border the channel material 104; in particular, the gate insulator 106 may contact the channel material 104 without any intervening material in some embodiments. In the embodiment of FIG. 1C, the gate stack comprising the gate insulator 106 and the gate electrode material 108 is shown as disposed on a support 102 in an orientation “upside down” to the one illustrated in FIG. 1A and FIG. 1B; that is, the gate electrode material 108 may be disposed between the support 102 and the channel material 104. The transistor 100 may include a first S/D region 114-1 and a second S/D region 114-2 disposed on the channel material 104 such that the first S/D region 114-1 and the second S/D region 114-2 are not coplanar with the channel material 104.

FIG. 1D depicts a transistor 100 having a single “bottom” gate provided by the gate electrode material 108 and the gate insulator 106. In FIG. 1D, the gate insulator 106 may be disposed between the gate electrode material 108 and the channel material 104. The gate insulator 106 may border the channel material 104; in particular, the gate insulator 106 may contact the channel material 104 without any intervening material in some embodiments. In the embodiment of FIG. 1D, the gate stack comprising the gate insulator 106 and the gate electrode material 108 is shown as disposed on a support 102 in an orientation “upside down” to the one illustrated in FIG. 1A and 1B; that is, the gate electrode material 108 may be disposed between the support 102 and the channel material 104. The transistor 100 of FIG. 1D may include a first S/D region 114-1 and a second S/D region 114-2 disposed on the channel material 104 such that at least some of the first S/D region 114-1 and at least some of the second S/D region 114-2 are coplanar with at least some of the channel material 104. In some embodiments, the first S/D region 114-1 and the second S/D region 114-2 may each be disposed between some of the channel material 104 and the support 102, as illustrated in FIG. 1D, while in other embodiments, the channel material 104 may not extend “above” the first S/D region 114-1 or the second S/D region 114-2. In some embodiments, the channel material 104 may conform around the first S/D region 114-1 and/or the second S/D region 114-2.

FIG. 1E depicts a double-gate transistor 100 having “bottom” and “top” gates provided by the gate electrode material 108-1/gate insulator 106-1 and the gate electrode material 108-2/gate insulator 106-2, respectively. The gate insulators 106-1 and 106-2 may include any of the materials or arrangements described for the gate insulator 106. In FIG. 1E, each gate insulator 106 may be disposed between the corresponding gate electrode material 108 and the channel material 104. Each gate insulator 106 may border the channel material 104; in particular, each gate insulator 106 may contact the channel material 104 without any intervening material in some embodiments. The transistor 100 may include a first S/D region 114-1 and a second S/D region 114-2 disposed proximate to the channel material 104. In the embodiment illustrated in FIG. 1E, the gate insulator 106-2 is disposed conformably around the first S/D region 114-1, the channel material 104, and the second S/D region 114-2. The gate electrode material 108-2 is disposed on the gate insulator 106-2. In the embodiment of FIG. 1E, at least some of the first S/D region 114-1 and at least some of the second S/D region 114-2 are coplanar with at least some of the gate insulator 106-2. The gate insulator 106-1 and the gate electrode material 108-1 of FIG. 1E may be arranged as described above for the gate insulator 106 and the gate electrode material 108 of FIG. 1C.

FIG. 1F depicts a double-gate transistor 100 having “bottom” and “top” gates provided by the gate electrode material 108-1/gate insulator 106-1 and the gate electrode material 108-2/gate insulator 106-2, respectively. In FIG. 1F, each gate insulator 106 may be disposed between the corresponding gate electrode material 108 and the channel material 104. Each gate insulator 106 may border the channel material 104; in particular, each gate insulator 106 may contact the channel material 104 without any intervening material in some embodiments. The transistor 100 may include a first S/D region 114-1 and a second S/D region 114-2 disposed proximate to the channel material 104. In the embodiment illustrated in FIG. 1F, the first S/D region 114-1 and the second S/D region 114-2 are coplanar with the channel material 104, and disposed between the gate insulators 106-1 and 106-2. As shown in FIG. 1F, the gate insulator 106-1 may be between the gate electrode material 108-1 and portions of the first S/D region 114-1, the channel material 104, and the second S/D region 114-2, while the gate electrode material 108-1 may be between the gate insulator 106-1 and the support 102. As further shown in FIG. 1F, the gate insulator 106-2 may be between the gate electrode material 108-2 and portions of the first S/D region 114-1, the channel material 104, and the second S/D region 114-2.

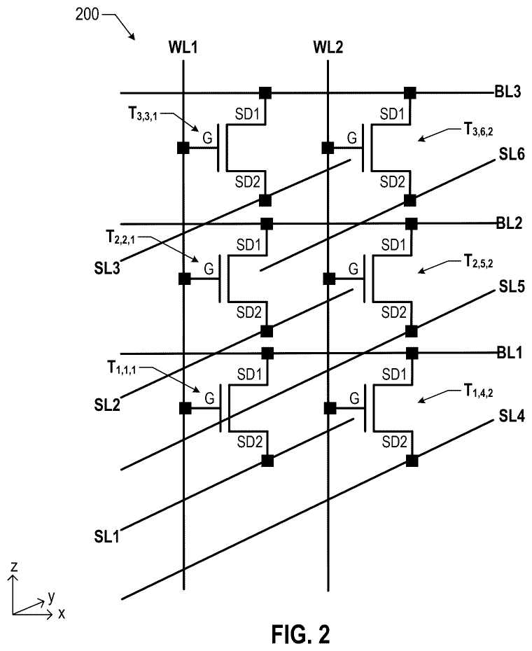

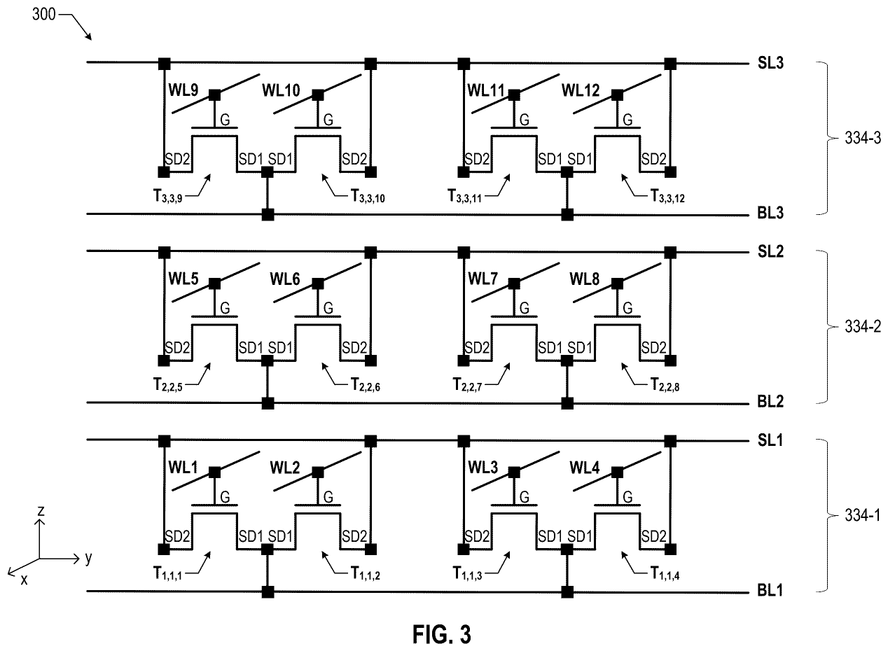

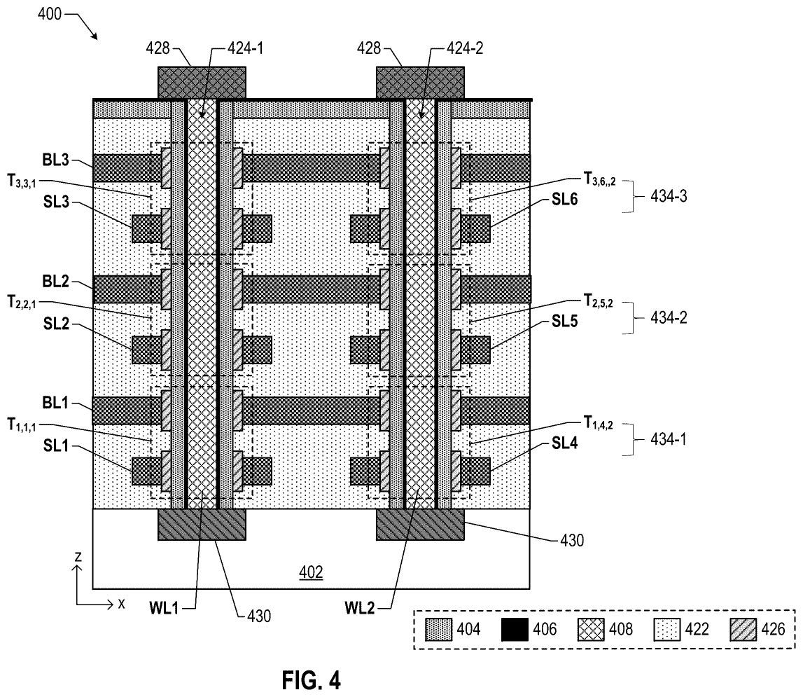

FIGS. 2-3 are electric circuit diagrams of two example arrays of floating body memory cells, according to some embodiments of the present disclosure. In each of FIGS. 2-3, individual transistors of different floating body memory cells are labeled as transistors T_{BL,SL,WL}, where the indices BL, SL, and WL indicate the respective bitline (BL), selectline (SL), and wordline (WL) to which a transistor T is coupled to. For example, a transistor T_{1,1,1} is coupled to BL1, SL1, and WL1, and so on. Each of the transistors T may be a FET (e.g., a transistor 100 as described above), having a gate terminal, a source terminal, and a drain terminal, labeled in FIGS. 2-3 as terminals G, S, and D, respectively. For each transistor T, a BL is coupled to a first S/D terminal/region of the transistor (e.g., to the first S/D region 114-1 as described above), an SL is coupled to a second S/D terminal/region of the transistor (e.g., to the second S/D region 114-2 as described above), and a WL is coupled to a gate (e.g., to the gate electrode material 108 as described above) of the transistor. Although a particular number of transistors, BLs, SLs, and WLs are shown in FIGS. 2-3, as well as in IC devices of FIGS. 4-5 showing example implementations of the electric circuit diagrams of FIGS. 2-3, in other embodiments, any suitable number of transistors, BLs, SLs, and WLs may be used in a floating body memory in accordance with the principles described herein.

FIG. 2 illustrates an array 200 where, for a given floating body memory cell (represented by different ones of the transistors T shown in FIG. 2), different ones of the WL, BL, and SL are parallel to different axes of a Cartesian coordinate system. For example, FIG. 2 illustrates that all of the BLs are parallel to the x-axis of the example x-y-z coordinate system shown, all SLs are parallel to the y-axis, and all WLs are parallel to the z-axis. In the array 200, some of the transistors T may be coupled to a single (i.e., shared) WL, while being coupled to different BLs and SLs. For example, as shown in FIG. 2, the transistors T_{1,1,1}, T_{2,2,1}, and T_{3,3,1} are coupled to a shared WL1 (where the transistor T_{1,1,1} is further coupled to BL1 and SL1, the transistor T_{2,2,1} is further coupled to BL2 and SL2, and the transistor T_{3,3,1} is further coupled to BL3 and SL3), while the transistors T_{1,4,2}, T_{2,5,2}, and T_{3,6,2} are coupled to a shared WL2 (where the transistor T_{1,4,2} is further coupled to BL1 and SL4, the transistor T_{2,5,2} is further coupled to BL2 and SL5, and the transistor T_{3,6,2} is further coupled to BL3 and SL6). Furthermore, in the array 200, some of the transistors T may be coupled to a single (i.e., shared) BL, while being coupled to different SLs and WLs. For example, as shown in FIG. 2, the transistors T_{1,1,1} and T_{1,4,2} are coupled to a shared BL1 (where the transistor T_{1,1,1} is further coupled to SL1 and WL1, and the transistor T_{1,4,2} is further coupled to SL4 and WL2), the transistors T_{2,2,1} and T_{2,5,2} are coupled to a shared BL2 (where the transistor T_{2,2,1} is further coupled to SL2 and WL1, and the transistor T_{2,5,2} is further coupled to SL5 and WL2), and the transistors T_{3,3,1} and T_{3,6,2} are coupled to a shared BL3 (where the transistor T_{3,3,1} is further coupled to SL3 and WL1, and the transistor T_{3,6,2} is further coupled to SL6 and WL2). In some embodiments, the array 200 may extend further along the y-axis by including additional two-dimensional (2D) planes similar to that shown in FIG. 2, containing additional 2D sub-arrays of floating body memory cells. In such embodiments, some of the transistors T may be coupled to a single (i.e., shared) SL, while being coupled to different BLs and WLs. For example, although not shown in FIG. 2, the transistor T_{1,1,1} and one or more further transistors in other x-z planes may be coupled to a shared SL1 while being coupled to different BLs and WLs.

FIG. 3 illustrates an array 300 where, for a given floating body memory cell (represented by different ones of the transistors T shown in FIG. 3), all of the WL, BL, and SL are in a layer parallel to an x-y plane of an example Cartesian coordinate system shown in the present drawings (i.e., parallel to a support structure over which the array 300 is provided), where BLs and SLs are substantially parallel to one another, and SL is substantially perpendicular to the BLs and SLs. For example, FIG. 3 illustrates that all of the WLs are parallel to the x-axis of the example x-y-z coordinate system shown, while all BLs and all SLs are parallel to the y-axis. In the array 300, some of the transistors T may be coupled to a single (i.e., shared) BL and, at the same time, also coupled to a single (i.e., shared) SL, while being coupled to different WLs. For example, as shown in FIG. 3, each of the transistors T_{1,1,1}, T_{1,1,2}, T_{1,1,3}, and T_{1,1,4} is coupled to a shared BL1 and a shared SL1, while being coupled to, respectively, WL1, WL2, WL3, and WL4. In another example, as shown in FIG. 3, each of the transistors T_{2,2,5}, T_{2,2,6}, T_{2,2,7}, and T_{2,2,8} is coupled to a shared BL2 and a shared SL2, while being coupled to, respectively, WL5, WL6, WL7, and WL8. In yet another example, as shown in FIG. 3, each of the transistors T_{3,3,9}, T_{3,3,10}, T_{3,3,11}, and T_{3,3,12} is coupled to a shared BL3 and a shared SL3, while being coupled to, respectively, WL9, WL10, WL11, and WL12. In some embodiments, all of the transistors coupled to a pair of a BL and an SL may be arranged in a respective layer 334 above the support structure, where different layers 334 may be vertically stacked above one another (i.e., stacked in the direction of the z-axis of the example coordinate system shown). This is shown in FIG. 3, illustrating that the transistors T_{1,1,1}, T_{1,1,2}, T_{1,1,3}, and T_{1,1,4} coupled to a shared BL1 and a shared SL1 are provided in a layer 334-1, the transistors T_{2,2,5}, T_{2,2,6}, T_{2,2,7}, and T_{2,2,8} coupled to a shared BL2 and a shared SL2 are provided in a layer 334-2, and the transistors T_{3,3,9}, T_{3,3,10}, T_{3,3,11}, and T_{3,3,12} coupled to a shared BL3 and a shared SL3 are provided in a layer 334-3. The layers 334 may be parallel to one another and parallel to the support structure over which the memory array 300 is provided. Individual layers 334 may be seen as 2D sub-arrays of floating body memory cells.

Furthermore, in some embodiments of the array 300, pairs of adjacent transistors in a given layer 334 may share a S/D region that is coupled to a BL or an SL. For example, in the first layer 334-1, the transistors T_{1,1,1} and T_{1,1,2} may share their first S/D region (SD1) that is coupled to the shared BL1, and so may the transistors T_{1,1,3} and T_{1,1,4}. In another example, in the second layer 334-2, the transistors T_{2,2,5} and T_{2,2,6} may share their first S/D region that is coupled to the shared BL2, and so may the transistors T_{2,2,7} and T_{2,2,8}. Similarly, in the third layer 334-3, the transistors T_{3,3,9} and T_{3,3,10} may share their first S/D region that is coupled to the shared BL3, and so may the transistors T_{3,3,11} and T_{3,3,12}. Although not specifically shown, in other embodiments of the array 300, adjacent transistors may share their second S/D region (SD2) that is coupled to the shared SL.

FIGS. 4-5 show example implementations of IC structures according to the electric circuit diagrams of FIGS. 2-3. In particular, FIG. 4 is a cross-sectional side view of an example IC structure implementing 3D floating body memory according to the electric circuit diagram of FIG. 2, while

FIGS. 5A-5B are cross-sectional side views of example IC structures implementing 3D floating body memory according to the electric circuit diagram of FIG. 3, according to various embodiments of the present disclosure. A number of elements referred to in the description of FIGS. 4-5 with reference numerals are illustrated in these drawings with different patterns, with a legend showing the correspondence between the reference numerals and patterns being provided at the bottom of each drawing page containing FIGS. 4-5. For example, the legend illustrates that FIGS. 4-5 use different patterns to show a support 402, a channel material 404, a gate electrode material 408, a gate insulator 406, and so on.

Turning to FIG. 4, an IC structure 400 is shown, where the IC structure 400 includes a support 402 and an insulator material 422 over the support 402. The support 402 may be an example of the support 102, described above. The insulator material 422 may include any suitable insulator materials described above, e.g., any suitable ILD material as described above. FIG. 4 further illustrates two openings 424-1 and 424-2 extending from the top of the insulator material 422 towards the support 402. In some embodiments, the openings 424 may be vias. While FIG. 4 illustrates that the openings 424 extend through all of the insulator material 422, stopping at the support 402, in other embodiments of the IC structure 400 this may not be the case and the openings 424 may end somewhere within the insulator material 422 without reaching the support 402. As shown in FIG. 4, a channel material 404 may be deposited to line sidewalls of the openings 424. Material composition and thickness of the channel material 404 may be as described above with reference to thin-film channel materials that may be included in the transistor 100.

Once the channel material 404 has been deposited on the sidewalls of the openings 424, the sidewalls may further be lined with a gate insulator 406 and then the remainder of the openings 424 may be filled with a gate electrode material 408. The gate insulator 406 and the gate electrode material 408 may be analogous to the gate insulator 106 and the gate electrode material 108 as described above with reference to the transistor 100. Although the same gate electrode material 408 is illustrated in both of the openings 424, in various embodiments, material compositions of the gate electrode materials 408 in different openings 424 may, but do not have to be, the same. Similarly, although the same channel material 404 and the gate insulator 406 are illustrated to line sidewalls of both of the openings 424, in various embodiments, material compositions of the channel materials 404 in different openings 424 may, but do not have to be, the same, and material compositions of the gate insulator 406 in different openings 424 may, but do not have to be, the same. Because the channel material 404 and the gate insulator 406 are deposited to line sidewalls of the openings 424 and then the openings 424 are filled with the gate electrode material 408, in the IC structure 400, for each of the openings 424, the gate insulator 406 may be a liner enclosing the gate electrode material 408, and the channel material 404 may be a liner enclosing the gate insulator 406.

FIG. 4 further illustrates a S/D interface material 426 that may be provided at an interface between S/D regions of the transistors formed based on the channel material 404 and respective BLs and SLs coupled to these S/D regions. The S/D interface material 426 may be any suitable electrically conductive material, provided because material composition of the BLs and SLs of the IC structure 400 may not be ideal for providing suitable contacts to S/D regions of the transistors of various floating body memory cells and the S/D interface material 426 may be used to ensure better contacts. In other embodiments of the IC structure 400, the S/D interface material 426 may be absent at one or more points where the BLs and SLs of the IC structure 400 need to make electrical contact with S/D regions of various transistors. When present, the S/D interface material 426 may be a liner enclosing the S/D regions in the channel material 404 around the openings 424.

The IC structure 400 of FIG. 4 is an example of the array 200 of FIG. 2 and, therefore, individual transistors T and control lines (i.e., BLs, SLs, and WLs) are labeled in FIG. 4 using the same notation as that used in FIG. 2 and descriptions provided with respect to FIG. 2 are applicable to FIG. 4 and, in the interests of brevity, are not repeated. FIG. 4 illustrates different rectangles to highlight approximate boundaries of different transistors. In the IC structure 400, the electrically conductive materials used as the gate electrode materials 408 in the openings 424 provide respective WLs, i.e., WL1 is formed by the gate electrode material 408 in the opening 424-1 and WL2 is formed by the gate electrode material 408 in the opening 424-2. Thus, in the IC structure 400, the WLs extend in a direction substantially perpendicular to the support 402. On the other hand, the BLs and the SLs extend in directions substantially parallel to the support 402, where the BLs are perpendicular to the SLs. Each of the transistors of various floating body memory cells of the IC structure 400 are vertical transistors, because the gate length (i.e., a distance between the first and second S/D regions of a transistor) is measured in the vertical direction (i.e., in a direction substantially perpendicular to the support 402).

FIG. 4 illustrates that, in some embodiments, transistors of the array 200 that are coupled to a single WL may be provided based on the channel material 404 deposited on sidewalls of a single opening 424, where different ones of these transistors have channel regions in different portions of that channel material 404. Thus, FIG. 4 illustrates that, in some embodiments, transistors of the array 200 that are coupled to a single WL may be vertically stacked above one another. For example, FIG. 4 illustrates that the transistors T_{1,1,1}, T_{2,2,1}, and T_{3,3,1}, coupled to a shared WL1, may be vertically stacked above one another and may have their channel regions in different portions of the channel material 404 on sidewalls of the opening 424-1. Similarly, FIG. 4 illustrates that the transistors T_{1,4,2}, T_{2,5,2}, and T_{3,6,2}, coupled to a shared WL2, may be vertically stacked above one another and may have their channel regions in different portions of the channel material 404 on sidewalls of the opening 424-2.

FIG. 4 further illustrates that, in some embodiments, transistors of the array 200 that are coupled to a single BL may be provided based on the channel materials 404 deposited on sidewalls of different openings 424, but where channel regions of different ones of these transistors may be substantially in the same layer with respect to the support 402. Thus, FIG. 4 illustrates that, in some embodiments, transistors of the array 200 that are coupled to a single BL may be arranged side-by-side with one another. For example, FIG. 4 illustrates that the transistors T_{1,1,1} and T_{1,4,2}, coupled to a shared BL1, may have their channel regions in a layer 434-1 above and parallel to the support 402. Similarly, FIG. 4 illustrates that the transistors T_{2,2,1} and T_{2,5,2}, coupled to a shared BL2, may have their channel regions in a layer 434-2 above and parallel to the support 402, while the transistors T_{3,3,1} and T_{3,6,2}, coupled to a shared BL3, may have their channel regions in a layer 434-3 above and parallel to the support 402.

FIG. 4 further illustrates gate contacts 428 and contacts 430. The gate contacts 428 may be in electric contact with the gate electrode material 408 in the openings 424 and may be used to apply signals to the gates. The contacts 430 may also be in electric contact with the gate electrode material 408 in the openings 424 and may be used to connect the WLs to row driver transistors (not shown).

FIG. 5A illustrates an IC structure 500 that is one example illustration of implementing the array 300 of FIG. 3. As shown in FIG. 5A, the IC structure 500 includes a support 502 and an insulator material 522 over the support 502. The support 502 may be an example of the support 102, described above. The insulator material 522 may include any suitable insulator materials described above, e.g., any suitable ILD material as described above. Furthermore, the IC structure 500 includes a plurality of layers 524 of a channel material 504, shown as layers 524-1, 524-2, and 524-3, extending through the insulator material 522, substantially parallel to the support 502, with their longitudinal axes being along the y-axis of the example coordinate system shown. The layers 524-1, 524-2, and 524-3 may be vertically stacked above one another above the support 502. Material composition and dimensions of the channel material 504 may be as described above with reference to the channel material 104 of the transistor 100.

Similar to the transistor 100, FIG. 5A illustrates how a gate insulator 506 and a gate electrode material 508 of different transistors of the floating body memory cells may be provided over portions of the channel material 504. The gate insulator 506 and the gate electrode material 508 may be analogous to the gate insulator 106 and the gate electrode material 108 as described above with reference to the transistor 100. Although FIG. 5A illustrates the same channel material 504, gate electrode material 508, and gate insulator 506 associated with different layers 524, in various embodiments, material compositions of the channel materials 504 of different layers 524 may, but do not have to be, the same, material compositions of any one or more of the channel material 504, gate electrode material 508, and gate insulator 506 associated with different layers 524 may, but do not have to be, the same.

FIG. 5A further illustrates S/D contacts 526 coupled to S/D regions in the layers 524. The S/D contacts 526 may be similar to the S/D interface material 426, described above. FIG. 5A further illustrates vias 528 between the S/D contacts 526 and respective BLs or SLs to which the S/D contacts 526 are coupled to. The vias 528 is one example of electrical interconnects that may be used to connect the S/D contacts 526 to respective BLs or SLs. In other embodiments of the IC structure 500, the S/D contacts 526 and/or the vias 528 may be absent, or interconnects of other types and geometry may be provided to ensure electrical connectivity between the S/D regions of various transistors provided based on the layers 524 and respective BLs and SLs.

The IC structure 500 of FIG. 5A is an example of the array 300 of FIG. 3 and, therefore, individual transistors T and control lines (i.e., BLs, SLs, and WLs) are labeled in FIG. 5A using the same notation as that used in FIG. 3 and descriptions provided with respect to FIG. 3 are applicable to FIG. 5A and, in the interests of brevity, are not repeated. The IC structure 500 includes 2D sub-arrays of floating body memory cells arranged in different layers 534, which layers are analogous to the layer 334 of the array 300. FIG. 5A illustrates different rectangles to highlight approximate boundaries of different transistors. In the IC structure 500, the electrically conductive materials used as the gate electrode materials 508 around the layers 524 provide respective WLs. Only WL1-WL4 of the first layer 534-1 are individually labeled in FIG. 5A and the WLs of the other layers 534 are not labeled in order to not clutter the drawing, but the individual designations of the other WLs are clear from the indices of the individual transistors labeled in FIG. 5A. For example, WL1 is formed by the gate electrode material 508 around a first portion of the layer 524-1, WL2 is formed by the gate electrode material 508 around a second portion of the layer 524-1, WL3 is formed by the gate electrode material 508 around a third portion of the layer 524-1, and WL4 is formed by the gate electrode material 508 around a fourth portion of the layer 524-1.

As shown in FIG. 5A, in the IC structure 500, the WLs extend in a direction substantially parallel to the support 502, e.g., in a direction parallel to the x-axis of the example coordinate system shown. The BLs and the SLs also extend in a direction substantially parallel to the support 502, but both BLs and SLs being substantially perpendicular to the WLs (thus, BLs and SLs are parallel to one another and extend in a direction parallel to the y-axis of the example coordinate system shown). Each of the transistors of various floating body memory cells of the IC structure 500 are horizontal transistors, because the gate length (i.e., a distance between the first and second S/D regions of a transistor) is measured in the horizontal direction (i.e., in a direction substantially parallel to the support 502).

FIG. 5A further illustrates how S/D regions of some of the adjacent transistors may be shared to couple them to the respective control line, as was described with reference to the array 300. For example, in the first layer 534-1, FIG. 5A illustrates a single S/D contact 526 shared by the transistors T_{1,1,1} and T_{1,1,2} to couple the first S/D regions of these transistors to the shared BL1, and further illustrates a single S/D contact 526 shared by the transistors T_{1,1,3} and T_{1,1,4} to couple the first S/D regions of these transistors to the shared BL1. Analogous applies to other layers 534. In some embodiments, the IC structure 500 may include a plug 530 in one or more of the layers 524 to electrically disconnect the S/D regions of transistors that do not share any of their S/D regions with one another. For example, a plug 530 may be included in the layer 524-1 between the closest S/D regions of the transistors T_{1,1,2} and T_{1,1,3}. Similarly, a plug 530 may be included in the layer 524-2 between the closest S/D regions of the transistors T_{2,2,6} and T_{2,2,7} and/or a plug 530 may be included in the layer 524-3 between the closest S/D regions of the transistors T_{3,3,10} and T_{3,3,11}. The plug 530 may include any suitable insulator material, e.g., any of the insulator materials described above.

FIG. 5A illustrates an embodiment where, in each layer 534, one of the BL and the SL is below the channel material 504 of the layer 534 and the other one is above the channel material. This means that a contact to the S/D region that is coupled to one of the BL and the SL is made from the top of the transistors T (i.e., from the side of the channel material 504 that is farthest away from the support 502), while a contact to the S/D region that is coupled to the other one of the BL and the SL is made from the bottom of the transistors T (i.e., from the side of the channel material 504 that is closest to the support 502). For example, in some embodiment, BLs may be below the channel material 504 in each layer 534, while SLs may be above the channel material 504 in each layer 534, as is shown in FIG. 5A. In other embodiments, both the BL and the SL for a given layer 534 may be arranged either above the channel material 504 of that layer or below the channel material 504 of that layer. An example where BLs and SLs are arranged above the channel material 504 of individual layers 534 is shown in FIG. 5B, illustrating an IC structure 500 that is substantially the same as the IC structure 500 of FIG. 5A except for this difference. Other descriptions provided with respect to the IC structure 500 of FIG. 5A are applicable to the IC structure 500 of FIG. 5B and, therefore, in the interest of brevity, are not repeated. The embodiment shown in FIG. 5A may be advantageous in terms of easier routing of BLs and SLs, while the embodiment shown in FIG. 5B may be advantageous in terms of easier manufacturing.

Any of the transistors shown in FIGS. 1-5 may be implemented with a transistor design where the difference between the work function of the first/second S/D contact and the conduction band of the channel portion is less than about 0.5 eV, and where the bandgap of the channel portion is between about 0.7 eV and about 2 eV. For example, for the transistors 100 shown in FIGS. 1A-1F, this may mean that the difference between the work function of a contact to any of the S/D regions 114 and the conduction band of the channel material 104 is less than about 0.5 eV, and the bandgap of the channel material 104 is between about 0.7 eV and about 2 eV. For the vertical transistors of FIG. 4, this may mean that the difference between the work function of the S/D interface material 426 and/or the BL/SL and the conduction band of the channel material 404 is less than about 0.5 eV, and the bandgap of the channel material 404 is between about 0.7 eV and about 2 eV. For the horizontal transistors of FIGS. 5A-5B, this may mean that the difference between the work function of the S/D contacts 526 and the conduction band of the channel material 504 is less than about 0.5 eV, and the bandgap of the channel material 504 is between about 0.7 eV and about 2 eV. In some embodiments, the bandgap of the channel materials 104, 404, or 504 may be greater than that of silicon.

In further embodiments, any of the transistors shown in FIGS. 1-5 may be implemented as asymmetric transistors, some examples of which are shown in FIGS. 6A-6D.

FIGS. 6A-6D are cross-sectional side views of example asymmetric transistors 600 that may be used in floating body memory, according to some embodiments of the present disclosure. FIGS. 6A-6D illustrate a channel material 604, a gate insulator 606, a gate electrode material 608, S/D regions 614-1 and 614-2 (together referred to as S/D regions 614), and S/D contacts 626-1 and 626-2 (together referred to as S/D contacts 626). FIGS. 6A-6D do not specifically show a support over which the channel material 604 is provided, but any of the IC structures that include the transistors 600 may include such a support, e.g., the support 102, the support 402, or the support 502 as shown in other drawings. Material composition and dimensions of the channel material 604 may be as described above with reference to the channel material 104 of the transistor 100. Furthermore, descriptions provided above with reference to the gate insulator 106, the gate electrode material 108, and the S/D regions 114 are applicable to, respectively, the gate insulator 606, the gate electrode material 608, and the S/D regions 614 shown in FIGS. 6A-6D. Still further, even though FIGS. 6A-6D illustrate one particular arrangement of the S/D contacts 626 (both on one side of the channel material 604, and both being on the same side as the channel material 604), in other embodiments, the transistors 600 may be of any suitable transistor architecture, such as any described with reference to FIGS. 1-5, or any other transistor architectures, such as FinFET or nanoribbon/nanowire transistors.

When a transistor 600 is used as a floating body memory cell, one of the S/D contacts 626 is used to write data to the cell, and another one of the S/D contacts 626 is used to read data from the cell. In FIGS. 6A-6D, it is assumed that the left side of the transistors 600 (i.e., the first S/D region 614-1 and the corresponding first S/D contact 626-1) is the write side, and the right side of the transistors 600 (i.e., the second S/D region 614-2 and the corresponding second S/D contact 626-2) is the read side. In various embodiments of asymmetric transistors 600, an additional layer of a semiconductor material may be disposed between a S/D contact 626, which typically includes a conductive material 642 such as a metal, a metal alloy, a carbide of a metal or a metal alloy, or a nitride of a metal or a metal alloy, and a corresponding S/D region 614.

FIG. 6A illustrates that a first semiconductor material 651 may be disposed between the conductive material 642 of the first S/D contact 626-1 and the first S/D region 614-1, and a second semiconductor material 652 may be disposed between the conductive material 642 of the second S/D contact 626-2 and the second S/D region 614-2, where a thickness of the first semiconductor material 651 may be smaller than a thickness of the second semiconductor material 652, e.g., at least about 10% smaller or at least about 15% smaller. In some embodiments, the first and second semiconductor materials 651 and 652 may have substantially the same material composition, e.g., in terms of their bandgap, doping concentration, or which one or more semiconductor materials are included in them. But even in such embodiments, having the thickness of the first semiconductor material 651 on the write side being smaller, e.g., being at least about 10% smaller or at least about 15% smaller, than the thickness of the second semiconductor material 652 on the read side of the transistor 600 may improve performance of the transistor 600 as a floating body memory cell in terms of charge confinement, leakage, and overall device reliability. In other embodiments, material compositions of the first semiconductor material 651 and the second semiconductor material 652 may be different. For example, in some embodiments, a dopant concentration of the first semiconductor material 651 may be higher than a dopant concentration of the second semiconductor material 652, e.g., at least about 2 times higher or at least about 5 times higher. In another example, in some embodiments, a bandgap of the first semiconductor material 651 may be smaller than a bandgap of the second semiconductor material 652, e.g., at least about 0.08 eV smaller or at least about 0.1 eV smaller. Such differences in terms of the dopant concentration and/or bandgaps of the first semiconductor material 651 on the write side and the second semiconductor material 652 on the read side of the transistor 600 may further improve performance of the transistor 600 as a floating body memory cell in terms of charge confinement, leakage, and overall device reliability. Still further improvements in terms of charge confinement, leakage, and overall device reliability may be obtained by selecting materials for the first semiconductor material 651, the second semiconductor material 652, the S/D regions 614, and the channel portion of the channel material 604 of FIG. 6A as described below.

In some embodiments of the transistor 600 of FIG. 6A, a dopant concentration of the first semiconductor material 651 may be at least about 2 times larger than a dopant concentration of the first S/D region 614-1, e.g., at least 5-10 times larger, or at least 100-1000 times larger. Similarly, in some embodiments, a dopant concentration of the second semiconductor material 652 may be at least about 2 times larger than a dopant concentration of the second S/D region 614-2, e.g., at least 5-10 times larger, or at least 100-1000 times larger. In some embodiments, a dopant concentration of one or both of the S/D regions 614 of the transistor 600 of FIG. 6A may be at least about 2 times larger than a dopant concentration of the channel portion of the channel material 604, e.g., at least 5-10 times larger, or at least 100-1000 times larger. In some embodiments, a dopant concentration of one or both of the S/D regions 614 of the transistor 600 of FIG. 6A may be at least about 10¹⁴ dopant atoms per cubic centimeter, e.g., at least about 10¹⁸ dopant atoms per cubic centimeter or at least about 10²⁰ dopant atoms per cubic centimeter. In some embodiments, a dopant concentration of one or both of the first semiconductor material 651 and the second semiconductor material 652 of the transistor 600 may be at least about 4 times larger than a dopant concentration of the channel portion of the channel material 604, e.g., at least 10-20 times larger, or at least 100-1000 times larger.

In some embodiments of the transistor 600 of FIG. 6A, the bandgap of the first semiconductor material 651 (e.g., an intrinsic bandgap) may be substantially same as the bandgap of the first S/D region 614-1. Similarly, in some embodiments, the bandgap of the second semiconductor material 652 may be substantially same as the bandgap of the second S/D region 614-2. In such embodiments, the first and/or second semiconductor materials 651, 652 and the first and/or second S/D regions 614-1, 614-2 may include substantially same semiconductor materials, but may have differences in thicknesses and/or differences in doping concentrations, as described above. In some embodiments, the bandgap of one or both of the S/D regions 614 of the transistor 600 of FIG. 6A may be at least 0.08 eV lower than the bandgap of the channel portion of the channel material 604, e.g., at least 0.1 eV lower, at least 0.2 eV lower, or at least 0.4 eV lower, e.g., the first/second S/D regions 614 and the channel material 604 of the channel portion may include different semiconductor materials. In some embodiments of FIG. 6A, a bandgap of the first and/or second semiconductor materials 651, 652 may be at least 0.08 eV lower than the bandgap of the corresponding S/D region 614, e.g., at least 0.1 eV lower, at least 0.2 eV lower, or at least 0.4 eV lower. For example, in such embodiments, the first and/or second semiconductor materials 651, 652 and the first and/or second S/D regions 614-1, 614-2 may include different semiconductor materials. In some embodiments, a bandgap of the first and/or second semiconductor materials 651, 652 may be at least 0.16 eV lower than the bandgap of the channel portion of the channel material 604, e.g., at least 0.2 eV lower, at least 0.4 eV lower, or at least 0.8 eV lower. For example, in such embodiments, the first and/or second semiconductor materials 651, 652 and the channel portion of the channel material 604 may include different semiconductor materials.

FIG. 6A illustrates an embodiment where the first semiconductor material 651 is deposited as a liner in an opening in an insulator material (not shown in FIG. 6A, but shown, e.g., in FIGS. 5A-5B) formed when fabricating the first S/D contact 626-1, the second semiconductor material 652 is deposited as a liner in an opening formed when fabricating the second S/D contact 626-2, and after that the conductive material 642 is deposited in the openings. As a result, the first and/or second semiconductor materials 651, 652 may be deposited on sidewalls and bottoms of the respective S/D contact 626. FIG. 6B illustrates a transistor 600 that may be substantially the same as the transistor 600 of FIG. 6A, except where the first and second semiconductor materials 651, 652 are not deposited on sidewalls of the S/D contacts 626, but are provided only between the conductive material 642 and the respective S/D regions 614. Other descriptions provided for the transistor 600 of FIG. 6A are applicable to the transistor 600 of FIG. 6B and, in the interests of brevity, are not repeated.

FIG. 6C illustrates that a first semiconductor material 661 may be disposed between the conductive material 642 of the first S/D contact 626-1 and the first S/D region 614-1, and a second semiconductor material 662 may be disposed between the conductive material 642 of the second S/D contact 626-2 and the second S/D region 614-2. As shown in FIG. 6C, a thickness of the first semiconductor material 661 may be substantially the same as a thickness of the second semiconductor material 662, but the dopant concentration of the first semiconductor material 661 may be higher than the dopant concentration of the second semiconductor material 662, e.g., at least about 2 times higher or at least about 5 times higher. In some embodiments, the first and second semiconductor materials 661 and 662 may have substantially the same bandgap, or which one or more semiconductor materials are included in them. But even in such embodiments, having the dopant concentration of the first semiconductor material 661 on the write side being higher, e.g., being at least 2 times higher or at least 5 times higher, than the dopant concentration of the second semiconductor material 662 on the read side of the transistor 600 may improve performance of the transistor 600 as a floating body memory cell in terms of charge confinement, leakage, and overall device reliability. In other embodiments, material compositions of the first semiconductor material 661 and the second semiconductor material 662 may be different. For example, in some embodiments, a bandgap of the first semiconductor material 661 may be smaller than a bandgap of the second semiconductor material 662, e.g., at least about 0.08 eV smaller or at least about 0.1 eV smaller. In some embodiments of FIG. 6C, a thickness of the first semiconductor material 661 may be smaller than a thickness of the second semiconductor material 662, e.g., at least about 10% smaller or at least about 15% smaller. In various embodiments, the first and second semiconductor materials 661, 662 may be implemented either as shown in FIG. 6A or in FIG. 6B. Such differences in terms of the bandgaps or thicknesses of the first semiconductor material 661 on the write side and the second semiconductor material 662 on the read side of the transistor 600 may further improve performance of the transistor 600 as a floating body memory cell in terms of charge confinement, leakage, and overall device reliability. Still further improvements in terms of charge confinement, leakage, and overall device reliability may be obtained by selecting materials for the first semiconductor material 661, the second semiconductor material 662, the S/D regions 614, and the channel portion of the channel material 604 of FIG. 6C as described below.

In some embodiments of the transistor 600 of FIG. 6C, a dopant concentration of the first semiconductor material 661 may be at least about 2 times larger than a dopant concentration of the first S/D region 614-1, e.g., at least 5-10 times larger, or at least 100-1000 times larger. Similarly, in some embodiments, a dopant concentration of the second semiconductor material 662 may be at least about 2 times larger than a dopant concentration of the second S/D region 614-2, e.g., at least 5-10 times larger, or at least 100-1000 times larger. In some embodiments, a dopant concentration of one or both of the S/D regions 614 of the transistor 600 of FIG. 6C may be at least about 2 times larger than a dopant concentration of the channel portion of the channel material 604, e.g., at least 5-10 times larger, or at least 100-1000 times larger. In some embodiments, a dopant concentration of one or both of the S/D regions 614 of the transistor 600 of FIG. 6C may be at least about 10¹⁴ dopant atoms per cubic centimeter, e.g., at least about 10¹⁸ dopant atoms per cubic centimeter or at least about 10²⁰ dopant atoms per cubic centimeter. In some embodiments, a dopant concentration of one or both of the first semiconductor material 661 and the second semiconductor material 662 of the transistor 600 may be at least about 4 times larger than a dopant concentration of the channel portion of the channel material 604, e.g., at least 10-20 times larger, or at least 100-1000 times larger.

In some embodiments of the transistor 600 of FIG. 6C, the bandgap of the first semiconductor material 661 (e.g., an intrinsic bandgap) may be substantially same as the bandgap of the first S/D region 614-1. Similarly, in some embodiments, the bandgap of the second semiconductor material 662 may be substantially same as the bandgap of the second S/D region 614-2. In such embodiments, the first and/or second semiconductor materials 661, 662 and the first and/or second S/D regions 614-1, 614-2 may include substantially same semiconductor materials, but may have differences in doping concentrations, as described above. In some embodiments, the bandgap of one or both of the S/D regions 614 of the transistor 600 of FIG. 6C may be at least 0.08 eV lower than the bandgap of the channel portion of the channel material 604, e.g., at least 0.1 eV lower, at least 0.2 eV lower, or at least 0.4 eV lower, e.g., the first/second S/D regions 614 and the channel material 604 of the channel portion may include different semiconductor materials. In some embodiments of FIG. 6C, a bandgap of the first and/or second semiconductor materials 661, 662 may be at least 0.08 eV lower than the bandgap of the corresponding S/D region 614, e.g., at least 0.1 eV lower, at least 0.2 eV lower, or at least 0.4 eV lower. For example, in such embodiments, the first and/or second semiconductor materials 661, 662 and the first and/or second S/D regions 614-1, 614-2 may include different semiconductor materials. In some embodiments, a bandgap of the first and/or second semiconductor materials 661, 662 may be at least 0.16 eV lower than the bandgap of the channel portion of the channel material 604, e.g., at least 0.2 eV lower, at least 0.4 eV lower, or at least 0.8 eV lower. For example, in such embodiments, the first and/or second semiconductor materials 661, 662 and the channel portion of the channel material 604 may include different semiconductor materials.

FIG. 6D illustrates that a first semiconductor material 671 may be disposed between the conductive material 642 of the first S/D contact 626-1 and the first S/D region 614-1, and a second semiconductor material 672 may be disposed between the conductive material 642 of the second S/D contact 626-2 and the second S/D region 614-2. As shown in FIG. 6D, a thickness of the first semiconductor material 671 may be substantially the same as a thickness of the second semiconductor material 672, but the bandgap of the first semiconductor material 671 may be smaller than the bandgap of the second semiconductor material 672, e.g., at least about 0.08 eV smaller or at least about 0.1 eV smaller. In some embodiments, the first and second semiconductor materials 671 and 672 may have substantially the same dopant concentrations and thicknesses. But even in such embodiments, having the bandgap of the first semiconductor material 671 on the write side being smaller, e.g., being at least about 0.08 eV smaller, than the bandgap of the second semiconductor material 672 on the read side of the transistor 600 may improve performance of the transistor 600 as a floating body memory cell in terms of charge confinement, leakage, and overall device reliability. In other embodiments, dopant concentrations of the first semiconductor material 671 and the second semiconductor material 672 may be different. For example, in some embodiments, a dopant concentration of the first semiconductor material 671 may be higher than a dopant concentration of the second semiconductor material 672, e.g., at least about 2 times higher or at least about 5 times higher. In some embodiments of FIG. 6D, a thickness of the first semiconductor material 671 may be smaller than a thickness of the second semiconductor material 672, e.g., at least about 10% smaller or at least about 15% smaller. In various embodiments, the first and second semiconductor materials 671, 672 may be implemented either as shown in FIG. 6A or in FIG. 6B. Such differences in terms of the dopant concentrations or thicknesses of the first semiconductor material 671 on the write side and the second semiconductor material 672 on the read side of the transistor 600 may further improve performance of the transistor 600 as a floating body memory cell in terms of charge confinement, leakage, and overall device reliability. Still further improvements in terms of charge confinement, leakage, and overall device reliability may be obtained by selecting materials for the first semiconductor material 671, the second semiconductor material 672, the S/D regions 614, and the channel portion of the channel material 604 of FIG. 6D as described below.

In some embodiments of the transistor 600 of FIG. 6D, a dopant concentration of the first semiconductor material 671 may be at least about 2 times larger than a dopant concentration of the first S/D region 614-1, e.g., at least 5-10 times larger, or at least 100-1000 times larger. Similarly, in some embodiments, a dopant concentration of the second semiconductor material 672 may be at least about 2 times larger than a dopant concentration of the second S/D region 614-2, e.g., at least 5-10 times larger, or at least 100-1000 times larger. In some embodiments, a dopant concentration of one or both of the S/D regions 614 of the transistor 600 of FIG. 6D may be at least about 2 times larger than a dopant concentration of the channel portion of the channel material 604, e.g., at least 5-10 times larger, or at least 100-1000 times larger. In some embodiments, a dopant concentration of one or both of the S/D regions 614 of the transistor 600 of FIG. 6D may be at least about 1014 dopant atoms per cubic centimeter, e.g., at least about 10¹⁸ dopant atoms per cubic centimeter or at least about 10²⁰ dopant atoms per cubic centimeter. In some embodiments, a dopant concentration of one or both of the first semiconductor material 671 and the second semiconductor material 672 of the transistor 600 may be at least about 4 times larger than a dopant concentration of the channel portion of the channel material 604, e.g., at least 10-20 times larger, or at least 100-1000 times larger.

In some embodiments of the transistor 600 of FIG. 6D, the bandgap of the first semiconductor material 671 (e.g., an intrinsic bandgap) may be substantially same as the bandgap of the first S/D region 614-1. Similarly, in some embodiments, the bandgap of the second semiconductor material 672 may be substantially same as the bandgap of the second S/D region 614-2. In such embodiments, the first and/or second semiconductor materials 671, 672 and the first and/or second S/D regions 614-1, 614-2 may include substantially same semiconductor materials, but may have differences in doping concentrations, as described above. In some embodiments, the bandgap of one or both of the S/D regions 614 of the transistor 600 of FIG. 6D may be at least 0.08 eV lower than the bandgap of the channel portion of the channel material 604, e.g., at least 0.1 eV lower, at least 0.2 eV lower, or at least 0.4 eV lower, e.g., the first/second S/D regions 614 and the channel material 604 of the channel portion may include different semiconductor materials. In some embodiments of FIG. 6D, a bandgap of the first and/or second semiconductor materials 671, 672 may be at least 0.08 eV lower than the bandgap of the corresponding S/D region 614, e.g., at least 0.1 eV lower, at least 0.2 eV lower, or at least 0.4 eV lower. For example, in such embodiments, the first and/or second semiconductor materials 671, 672 and the first and/or second S/D regions 614-1, 614-2 may include different semiconductor materials. In some embodiments, a bandgap of the first and/or second semiconductor materials 671, 672 may be at least 0.16 eV lower than the bandgap of the channel portion of the channel material 604, e.g., at least 0.2 eV lower, at least 0.4 eV lower, or at least 0.8 eV lower. For example, in such embodiments, the first and/or second semiconductor materials 671, 672 and the channel portion of the channel material 604 may include different semiconductor materials.

Various arrangements of the IC structures showing various transistor designs as illustrated in FIGS. 1-6 do not represent an exhaustive set of transistor designs that may implement floating body memory as described herein, but merely provide examples of such devices/structures/assemblies. For example, while FIG. 5A illustrates an SL being above the channel material 504 and a BL being below the channel material 504 in each of the layers 534, in other embodiments, this may be reversed for one or more layers 534 (i.e., a BL may be above the channel material 504 and an SL may be below the channel material 504 for one or more layers 534). Similarly, while FIG. 5B illustrates both an SL and a BL being above the channel material 504 in each of the layers 534, in other embodiments, this may be reversed for one or more layers 534 (i.e., both an SL and a BL may be below the channel material 504 for one or more layers 534). In another example, while FIG. 5B illustrates a BL being further away from the channel material 504 than an SL in each of the layers 534, in other embodiments, this may be reversed for one or more layers 534 (i.e., an SL may be further away from the channel material 504 than a BL for one or more layers 534). In yet another example, while FIGS. 5A and 5B illustrate top-gated transistors T (i.e., for each transistor, the gate electrode material 508 is provided further away from the support 502 than the corresponding channel material 504), in other embodiments, at least some of the transistors may be bottom-gated transistors (i.e., for one or more layers 534 or for one or more transistors within a given layer 534, the gate electrode material 508 may be provided closer to the support 502 than the corresponding channel material 504). The number and positions of various elements shown in FIGS. 1-6 is purely illustrative and, in various other embodiments, other numbers of these elements, provided in other locations relative to one another may be used in accordance with the general architecture considerations described herein.

Arrangements with one or more transistor designs for floating body memory as disclosed herein may be included in any suitable electronic device. FIGS. 7-11 illustrate various examples of devices and components that may include one or more IC structures implementing transistor designs for floating body memory as disclosed herein, e.g., any of the IC structures as shown in FIG. 1-6, or any combination of such IC structures.

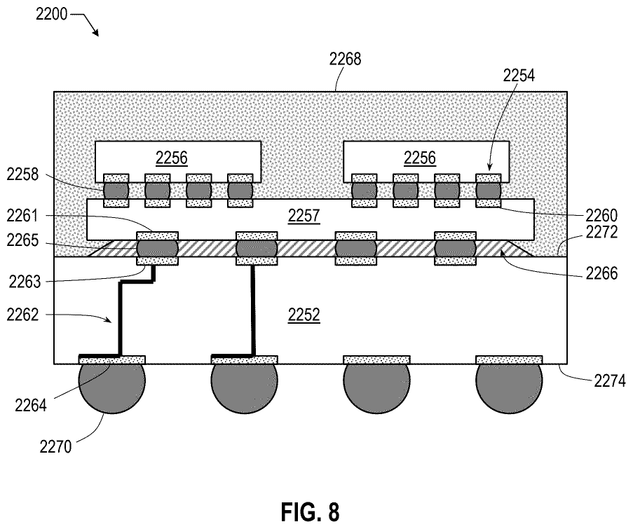

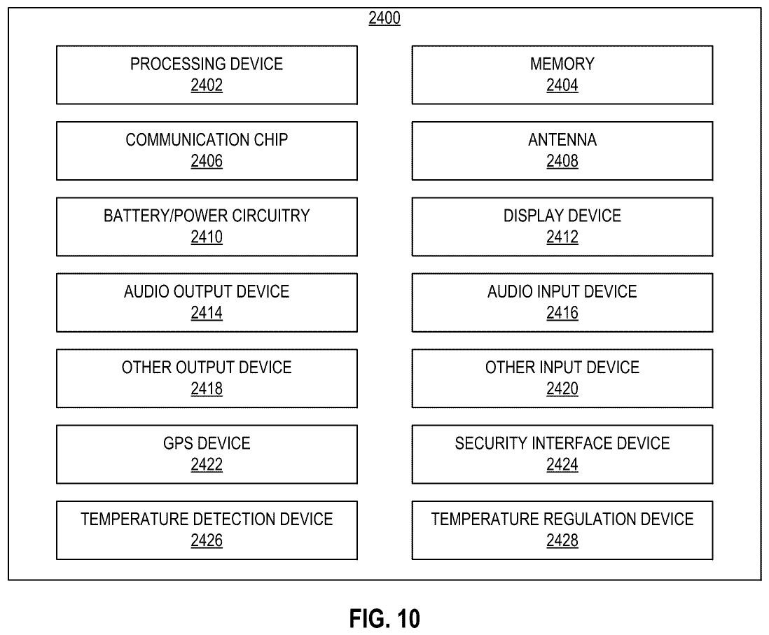

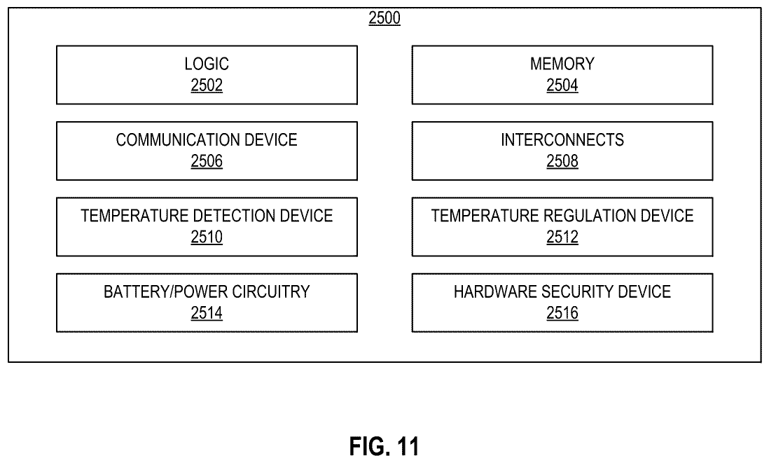

FIG. 7 illustrates top views of a wafer 2000 and dies 2002 that may include one or more IC structures implementing transistor designs for floating body memory in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 8. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more transistor designs for floating body memory as described herein). After the fabrication of the semiconductor product is complete (e.g., after manufacture of any embodiment of the IC structures as shown in FIG. 1-6, or any combination of such IC structures), the wafer 2000 may undergo a singulation process in which each of the dies 2002 is separated from one another to provide discrete “chips” of the semiconductor product. In particular, devices that include one or more IC structures implementing transistor designs for floating body memory as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device (e.g., a floating body memory as described herein), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 10 or the logic circuitry 2502 of FIG. 11) or other logic that is configured to store information in the memory devices or execute instructions stored in the memory array.

FIG. 8 is a side, cross-sectional view of an example IC package 2200 that may include one or more IC structures implementing transistor designs for floating body memory in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 8 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 8 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

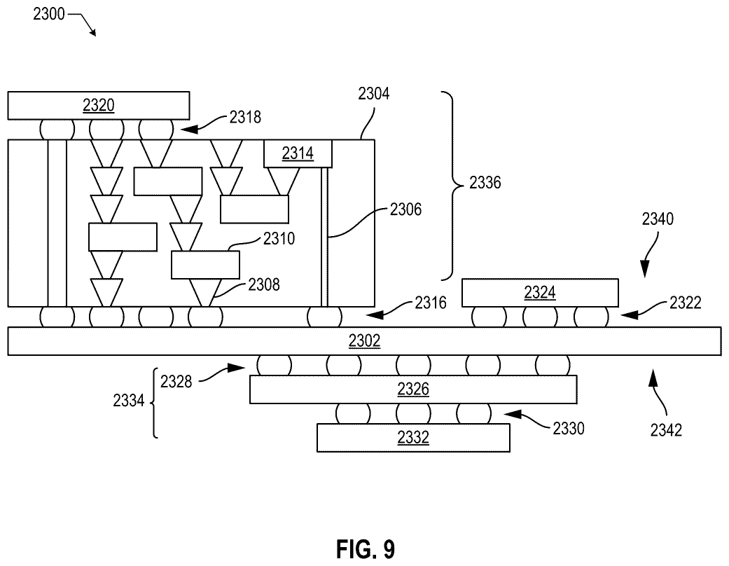

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 8 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 9.

The dies 2256 may take the form of any of the embodiments of the die 2002 discussed herein (e.g., may include any of the embodiments of the IC structures implementing transistor designs for floating body memory as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory) with floating body memory, including embedded memory dies, as described herein. In some embodiments, any of the dies 2256 may include one or more IC structures implementing transistor designs for floating body memory, e.g., as discussed above; in some embodiments, at least some of the dies 2256 may not include any IC structures implementing transistor designs for floating body memory as described herein.

The IC package 2200 illustrated in FIG. 8 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 8, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 9 is a cross-sectional side view of an IC device assembly 2300 that may include components having one or more IC structures implementing transistor designs for floating body memory in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more IC structures implementing transistor designs for floating body memory in accordance with any of the embodiments disclosed herein; e.g., any of the IC packages discussed below with reference to the IC device assembly 2300 may take the form of any of the embodiments of the IC package 2200 discussed above with reference to FIG. 8 (e.g., may include one or more IC structures implementing transistor designs for floating body memory provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 9 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 9), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 7), an IC device, or any other suitable component. In particular, the IC package 2320 may include one or more IC structures implementing transistor designs for floating body memory as described herein. Although a single IC package 2320 is shown in FIG. 9, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 9, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 9 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 10 is a block diagram of an example computing device 2400 that may include one or more components including floating body memory in accordance with any of the embodiments disclosed herein. For example, any suitable ones of the components of the computing device 2400 may include a die (e.g., the die 2002 of FIG. 7) having one or more IC structures implementing transistor designs for floating body memory as described herein. Any one or more of the components of the computing device 2400 may include, or be included in, an IC package 2200 of FIG. 8 or an IC device assembly 2300 of FIG. 9.

A number of components are illustrated in FIG. 10 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 10, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), non-volatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM. In some embodiments, the memory 2404 may include one or more IC structures implementing transistor designs for floating body memory as described herein.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 11 is a block diagram of an example processing device 2500 that may include one or more components including floating body memory in accordance with any of the embodiments disclosed herein. For example, any suitable ones of the components of the processing device 2500 may include a die (e.g., the die 2002 of FIG. 7) having one or more IC structures implementing transistor designs for floating body memory as described herein. Any one or more of the components of the processing device 2500 may include, or be included in, an IC device assembly 2300 (FIG. 9). Any one or more of the components of the processing device 2500 may include, or be included in, an IC package 2200 of FIG. 8 or an IC device assembly 2300 of FIG. 9. Any one or more of the components of the processing device 2500 may include, or be included in, a computing device 2400 of FIG. 10; for example, the processing device 2500 may be the processing device 2402 of the computing device 2400.

A number of components are illustrated in FIG. 11 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 11, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 10). In some embodiments, the memory 2504 may be a designated device configured to provide storage functionality for the components of the processing device 2500 (e.g., local), while the memory 1604 may be configured to provide system-level storage functionality for the entire computing device 2400 (e.g., global). In some embodiments, the memory 2504 may include memory that shares a die with the logic circuitry 2502. In some embodiments, the memory 2504 may include one or more IC structures implementing transistor designs for floating body memory.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, e.g., the size and capabilities of each component. With hierarchical memory, each of the various memory components can be viewed as part of a hierarchy of memories (m₁, m₂, . . . , mₙ) in which each member mi is typically smaller and faster than the next highest member min of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 10). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, MIM structures, etc.

The processing device 2500 may include a temperature detection device 2510 which may be implemented substantially as described above with reference to the temperature detection device 2426 of FIG. 10 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 10 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 10. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 10. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide various examples of the embodiments disclosed herein.

Example 1 provides an IC structure that includes a substrate (or, more generally, a support such as a substrate, a wafer, a die, or a chip); a channel material over the substrate; a transistor, including a first region, a second region, and a channel portion between the first region and the second region, where the channel portion of the transistor is a portion of the channel material, and where one of the first region and the second region is a source region of the transistor and another one of the first region and the second region is a drain region of the transistor; a first contact coupled to the first region; a second contact coupled to the second region; a first semiconductor material between the first contact and the first region; and a second semiconductor material between the second contact and the second region, where a thickness of the first semiconductor material is smaller than a thickness of the second semiconductor material, e.g., at least about 10% smaller or at least about 15% smaller.

Example 2 provides the IC structure according to example 1, where a dopant concentration of the first/second semiconductor material is at least about 2 times larger than a dopant concentration of the first/second region, e.g., at least 5-10 times larger, or at least 100-1000 times larger.

Example 3 provides the IC structure according to example 2, where the dopant concentration of the first/second region is at least about 2 times larger than a dopant concentration of the channel portion, e.g., at least 5-10 times larger, or at least 100-1000 times larger.

Example 4 provides the IC structure according to example 1, where a dopant concentration of the first/second semiconductor material is at least about 4 times larger than a dopant concentration of the channel portion, e.g., at least 10-20 times larger, or at least 100-1000 times larger.

Example 5 provides the IC structure according to any one of examples 1-4, where a dopant concentration of the first/second region is at least about 10¹⁴ dopant atoms per cubic centimeter, e.g., at least about 10¹⁸ dopant atoms per cubic centimeter or at least about 10²⁰ dopant atoms per cubic centimeter.

Example 6 provides the IC structure according to any one of examples 1-5, where a bandgap (e.g., an intrinsic bandgap) of the first/second semiconductor material is substantially same as a bandgap of the first/second region (i.e., the first/second semiconductor material and the first/second region may include substantially same semiconductor materials, but may have differences in doping concentrations, e.g., as in claims 2-4).

Example 7 provides the IC structure according to any one of examples 1-5, where a bandgap of the first/second region is at least 0.08 eV lower, e.g., at least 0.1 eV lower, at least 0.2 eV lower, or at least 0.4 eV lower, than a bandgap of the channel portion (e.g., the first/second region and the channel material of the channel portion are different semiconductor materials).

Example 8 provides the IC structure according to example 7, where a bandgap of the first/second semiconductor material is at least 0.08 eV lower, e.g., at least 0.1 eV lower, at least 0.2 eV lower or at least 0.4 eV lower, than the bandgap of the first/second region (e.g., the first/second semiconductor material and the first/second region are different semiconductor materials).

Example 9 provides the IC structure according to any one of examples 1-5, where a bandgap of the first/second semiconductor material is at least 0.16 eV lower than a bandgap of the channel portion, e.g., at least 0.2 eV lower, at least 0.4 eV lower or at least 0.8 eV lower (e.g., the first/second semiconductor material and the channel material of the channel portion are different semiconductor materials).

Example 10 provides the IC structure according to any one of examples 1-9, where a material composition of the first semiconductor material and a material composition of the second semiconductor material are substantially same.

Example 11 provides the IC structure according to any one of examples 1-9, where a material composition of the first semiconductor material is different from a material composition of the second semiconductor material.

Example 12 provides the IC structure according to example 11, where a dopant concentration of the first semiconductor material is higher than a dopant concentration of the second semiconductor material, e.g., at least about 2 times higher or at least about 5 times higher.

Example 13 provides the IC structure according to examples 11 or 12, where a bandgap of the first semiconductor material is smaller than a bandgap of the second semiconductor material, e.g., at least about 0.08 eV smaller or at least about 0.1 eV smaller.

Example 14 provides an IC structure that includes a substrate; a channel material over the substrate; a transistor, including a first region, a second region, and a channel portion between the first region and the second region, where the channel portion of the transistor is a portion of the channel material, and where one of the first region and the second region is a source region of the transistor and another one of the first region and the second region is a drain region of the transistor; a first contact coupled to the first region; a second contact coupled to the second region; a first semiconductor material between the first contact and the first region; and a second semiconductor material between the second contact and the second region, where a dopant concentration of the first semiconductor material is higher than a dopant concentration of the second semiconductor material, e.g., at least about 2 times higher or at least about 5 times higher.

Example 15 provides the IC structure according to example 14, where a bandgap of the first semiconductor material is smaller than a bandgap of the second semiconductor material, e.g., at least about 0.08 eV smaller or at least about 0.1 eV smaller.

Example 16 provides the IC structure according to examples 14 or 15, where a material composition of the first semiconductor material is different from a material composition of the second semiconductor material.

Example 17 provides the IC structure according to example 13, where a bandgap of the first semiconductor material is substantially equal to a bandgap of the second semiconductor material.

Example 18 provides the IC structure according to examples 14 or 17, where a material composition of the first semiconductor material and a material composition of the second semiconductor material are substantially same.

Example 19 provides the IC structure according to any one of examples 14-18, where the dopant concentration of the first/second semiconductor material is at least about 2 times larger than a dopant concentration of the first/second region, e.g., at least 5-10 times larger, or at least 100-1000 times larger.

Example 20 provides the IC structure according to example 19, where the dopant concentration of the first/second region is at least about 2 times larger than a dopant concentration of the channel portion, e.g., at least 5-10 times larger, or at least 100-1000 times larger.

Example 21 provides the IC structure according to any one of examples 14-18, where a dopant concentration of the first/second semiconductor material is at least about 4 times larger than a dopant concentration of the channel portion, e.g., at least 10-20 times larger, or at least 100-1000 times larger.

Example 22 provides the IC structure according to any one of examples 14-21, where a dopant concentration of the first/second region is at least about 10¹⁴ dopant atoms per cubic centimeter, e.g., at least about 10¹⁸ dopant atoms per cubic centimeter or at least about 10²⁰ dopant atoms per cubic centimeter.

Example 23 provides the IC structure according to any one of examples 14-22, where a bandgap (e.g., an intrinsic bandgap) of the first/second semiconductor material is substantially same as a bandgap of the first/second region (i.e., the first/second semiconductor material and the first/second region may include substantially same semiconductor materials, but may have differences in doping concentrations, e.g., as in claims 19-21).

Example 24 provides the IC structure according to any one of examples 14-22, where a bandgap of the first/second region is at least 0.08 eV lower than a bandgap of the channel portion, e.g., at least 0.1 eV lower, at least 0.2 eV lower, or at least 0.4 eV lower (e.g., the first/second region and the channel material of the channel portion are different semiconductor materials).

Example 25 provides the IC structure according to example 24, where a bandgap of the first/second semiconductor material is at least 0.08 eV lower than the bandgap of the first/second region, e.g., at least 0.1 eV lower, at least 0.2 eV lower, or at least 0.4 eV lower (e.g., the first/second semiconductor material and the first/second region are different semiconductor materials).

Example 26 provides the IC structure according to any one of examples 14-22, where a bandgap of the first/second semiconductor material is at least 0.08 eV lower than a bandgap of the first/second region, e.g., at least 0.1 eV lower, at least 0.2 eV lower, or at least 0.4 eV lower (e.g., the first/second semiconductor material and the first/second region are different semiconductor materials).

Example 27 provides the IC structure according to any one of examples 14-26, where a thickness of the first semiconductor material is smaller than a thickness of the second semiconductor material, e.g., at least about 10% smaller or at least about 15% smaller.

Example 28 provides an IC structure that includes a substrate; a channel material over the substrate; a transistor, including a first region, a second region, and a channel portion between the first region and the second region, where the channel portion of the transistor is a portion of the channel material, and where one of the first region and the second region is a source region of the transistor and another one of the first region and the second region is a drain region of the transistor; a first contact coupled to the first region; a second contact coupled to the second region; a first semiconductor material between the first contact and the first region; and a second semiconductor material between the second contact and the second region, where a bandgap of the first semiconductor material is smaller than a bandgap of the second semiconductor material, e.g., at least about 0.08 eV smaller or at least about 0.1 eV smaller.

Example 29 provides the IC structure according to example 28, where a dopant concentration of the first semiconductor material is higher than a dopant concentration of the second semiconductor material, e.g., at least about 2 times higher or at least about 5 times higher.

Example 30 provides the IC structure according to examples 28 or 29, where a material composition of the first semiconductor material is different from a material composition of the second semiconductor material.

Example 31 provides the IC structure according to any one of examples 28-30, where the dopant concentration of the first/second semiconductor material is at least about 2 times larger than a dopant concentration of the first/second region, e.g., at least 5-10 times larger, or at least 100-1000 times larger.

Example 32 provides the IC structure according to example 31, where the dopant concentration of the first/second region is at least about 2 times larger than a dopant concentration of the channel portion, e.g., at least 5-10 times larger, or at least 100-1000 times larger.

Example 33 provides the IC structure according to any one of examples 28-30, where a dopant concentration of the first/second semiconductor material is at least about 4 times larger than a dopant concentration of the channel portion, e.g., at least 10-20 times larger, or at least 100-1000 times larger.

Example 34 provides the IC structure according to any one of examples 28-33, where a dopant concentration of the first/second region is at least about 10¹⁴ dopant atoms per cubic centimeter, e.g., at least about 10¹⁸ dopant atoms per cubic centimeter or at least about 10²⁰ dopant atoms per cubic centimeter.

Example 35 provides the IC structure according to any one of examples 28-34, where a bandgap (e.g., an intrinsic bandgap) of the first/second semiconductor material is substantially same as a bandgap of the first/second region (i.e., the first/second semiconductor material and the first/second region may include substantially same semiconductor materials, but may have differences in doping concentrations, e.g., as in claims 19-21).

Example 36 provides the IC structure according to any one of examples 28-34, where a bandgap of the first/second region is at least 0.08 eV lower than a bandgap of the channel portion, e.g., at least 0.1 eV lower, at least 0.2 eV lower, or at least 0.4 eV lower (e.g., the first/second region and the channel material of the channel portion are different semiconductor materials).

Example 37 provides the IC structure according to example 36, where a bandgap of the first/second semiconductor material is at least 0.08 eV lower than the bandgap of the first/second region, e.g., at least 0.1 eV lower, at least 0.2 eV lower, or at least 0.4 eV lower (e.g., the first/second semiconductor material and the first/second region are different semiconductor materials).

Example 38 provides the IC structure according to any one of examples 28-34, where a bandgap of the first/second semiconductor material is at least 0.16 eV lower than a bandgap of the channel portion, e.g., at least 0.2 eV lower, at least 0.4 eV lower, or at least 0.8 eV lower (e.g., the first/second semiconductor material and the first/second region are different semiconductor materials).

Example 39 provides the IC structure according to any one of examples 28-38, where a thickness of the first semiconductor material is smaller than a thickness of the second semiconductor material, e.g., at least about 10% smaller or at least about 15% smaller.

Example 40 provides the IC structure according to any one of the preceding examples, where a difference between a work function of the first/second contact and a conduction band of the channel portion is less than about 0.5 eV.

Example 41 provides the IC structure according to any one of the preceding examples, where a bandgap of the channel portion is greater than a bandgap of silicon.

Example 42 provides the IC structure according to any one of the preceding examples, where a bandgap of the channel portion is between about 0.7 eV and about 2 eV.

Example 43 provides the IC structure according to any one of the preceding examples, where the channel material is a thin-film semiconductor material.

Example 44 provides an IC structure that includes a substrate; a thin-film semiconductor material over the substrate; a transistor, including a first region, a second region, and a channel portion between the first region and the second region, where the channel portion of the transistor is a portion of the thin-film semiconductor material, and where one of the first region and the second region is a source region of the transistor and another one of the first region and the second region is a drain region of the transistor; and a contact coupled to the first region, where a difference between a work function of the first contact and a conduction band of the channel portion is less than about 0.5 eV, and a bandgap of the channel portion is between about 0.7 eV and about 2 eV.

Example 45 provides the IC structure according to example 44, where the dopant concentration of the first region is at least about 2 times larger than a dopant concentration of the channel portion, e.g., at least 5-10 times larger, or at least 100-1000 times larger.

Example 46 provides the IC structure according to examples 44 or 45, where a dopant concentration of the first region is at least about 10¹⁴ dopant atoms per cubic centimeter, e.g., at least about 10¹⁸ dopant atoms per cubic centimeter or at least about 10²⁰ dopant atoms per cubic centimeter.

Example 47 provides the IC structure according to any one of examples 44-46, where a bandgap of the first region is at least 0.08 eV lower than a bandgap of the channel portion, e.g., at least 0.1 eV lower, at least 0.2 eV lower, or at least 0.4 eV lower (e.g., the first/second region and the channel material of the channel portion are different semiconductor materials).

Example 48 provides the IC structure according to any one of examples 44-47, where the contact is a first contact, and the IC structure further includes a second contact coupled to the second region.

Example 49 provides an IC package that includes an IC die, including an IC structure according to any one of the preceding examples (e.g., any one of claims 1-48); and a further component, coupled to the IC die.

Example 50 provides the IC package according to example 49, where the further component is one of a package substrate, an interposer, or a further IC die.

In various further examples of the IC package according to examples 49 or 50, the further component may be coupled to the IC die via one or more first-level interconnects, where the one or more first-level interconnects may include one or more solder bumps, solder posts, or bond wires.

In further examples of the IC package according to any of the preceding examples, the IC die includes, or is a part of, at least one of a memory device, a computing device, a wearable device, a handheld electronic device, and a wireless communications device.

Example 51 provides an electronic device, including a carrier substrate; and one or more of the IC devices according to any one of the preceding examples and/or the IC package according to any one of the preceding claims, coupled to the carrier substrate.

Example 52 provides the electronic device according to example 51, where the carrier substrate is a motherboard.

Example 53 provides the electronic device according to example 51, where the carrier substrate is a PCB.

Example 54 provides the electronic device according to any one of examples 51-53, where the electronic device is a wearable electronic device (e.g., a smart watch) or handheld electronic device (e.g., a mobile phone).

Example 55 provides the electronic device according to any one of examples 51-54, where the electronic device further includes one or more communication chips and an antenna.

Example 56 provides the electronic device according to any one of examples 51-55, where the electronic device is memory device.

Example 57 provides the electronic device according to any one of examples 51-55, where the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 58 provides the electronic device according to any one of examples 51-55, where the electronic device is a computing device.

Example 59 provides the electronic device according to any one of examples 51-58, where the electronic device is included in a base station of a wireless communication system.

Example 60 provides the electronic device according to any one of examples 51-58, where the electronic device is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a substrate;
a channel material over the substrate;
a transistor, comprising a first region, a second region, and a channel portion between the first region and the second region, wherein the channel portion of the transistor is a portion of the channel material, and wherein one of the first region and the second region is a source region of the transistor and another one of the first region and the second region is a drain region of the transistor;
a first contact coupled to the first region;
a second contact coupled to the second region;
a first semiconductor material between the first contact and the first region; and
a second semiconductor material between the second contact and the second region,
wherein a thickness of the first semiconductor material is smaller than a thickness of the second semiconductor material.

2. The IC structure according to claim 1, wherein a dopant concentration of the first semiconductor material is at least about 2 times larger than a dopant concentration of the first region.

3. The IC structure according to claim 2, wherein the dopant concentration of the first region is at least about 2 times larger than a dopant concentration of the channel portion.

4. The IC structure according to claim 1, wherein a dopant concentration of the first semiconductor material is at least about 4 times larger than a dopant concentration of the channel portion.

5. The IC structure according to claim 1, wherein a dopant concentration of the first region is at least about 10¹⁴ dopant atoms per cubic centimeter.

6. The IC structure according to claim 1, wherein a bandgap of the first semiconductor material is substantially same as a bandgap of the first region.

7. The IC structure according to claim 1, wherein a bandgap of the first region is at least 0.08 electron-Volt lower than a bandgap of the channel portion.

8. The IC structure according to claim 7, wherein a bandgap of the first semiconductor material is at least 0.08 electron-Volt lower than the bandgap of the first region.

9. The IC structure according to claim 1, wherein a bandgap of the first semiconductor material is at least 0.16 electron-Volt lower than a bandgap of the channel portion.

10. The IC structure according to claim 1, wherein a material composition of the first semiconductor material and a material composition of the second semiconductor material are substantially same.

11. The IC structure according to claim 1, wherein a material composition of the first semiconductor material is different from a material composition of the second semiconductor material.

12. The IC structure according to claim 11, wherein a dopant concentration of the first semiconductor material is at least 2 times higher than a dopant concentration of the second semiconductor material.

13. The IC structure according to claim 11, wherein a bandgap of the first semiconductor material is smaller than a bandgap of the second semiconductor material.

14. An integrated circuit (IC) structure, comprising:
a first semiconductor material;
a transistor, comprising a first region, a second region, and a channel portion comprising a portion of the first semiconductor material, and wherein one of the first region and the second region is a source region of the transistor and another one of the first region and the second region is a drain region of the transistor;
a first contact coupled to the first region;
a second contact coupled to the second region;
a second semiconductor material between the first contact and the first region; and
a third semiconductor material between the second contact and the second region,
wherein a dopant concentration of the second semiconductor material is at least 2 times higher than a dopant concentration of the third semiconductor material.

15. The IC structure according to claim 14, wherein a bandgap of the second semiconductor material is smaller than a bandgap of the third semiconductor material.

16. The IC structure according to claim 14, wherein a thickness of the second semiconductor material is at least 10 percent smaller than a thickness of the third semiconductor material.

17. An integrated circuit (IC) structure, comprising:
a thin-film semiconductor material;
a transistor, comprising a first region, a second region, and a channel portion comprising a portion of the thin-film semiconductor material, and wherein one of the first region and the second region is a source region of the transistor and another one of the first region and the second region is a drain region of the transistor;
a first contact coupled to the first region;
a second contact coupled to the second region;
a first semiconductor material between the first contact and the first region; and
a second semiconductor material between the second contact and the second region,
wherein a bandgap of the first semiconductor material is at least 0.08 electron-Volt smaller than a bandgap of the second semiconductor material.

18. The IC structure according to claim 17, wherein a dopant concentration of the first semiconductor material is higher than a dopant concentration of the second semiconductor material.

19. The IC structure according to claim 17, wherein a thickness of the first semiconductor material is smaller than a thickness of the second semiconductor material.

20. The IC structure according to claim 17, wherein a difference between a work function of the first contact and a conduction band of the channel portion is less than about 0.5 electron-Volt.
